(19) United States
(12) Patent Application Publication
(10) Pub. No.: US 2025/0374450 A1
(43) Pub. Date: Dec. 4, 2025

(54) DISPLAY MODULE AND ELECTRONIC DEVICE INCLUDING THE SAME

(71) Applicant: SAMSUNG ELECTRONICS CO., LTD., Suwon-si (KR)

(72) Inventors: Dongsool HONG, Suwon-si (KR); Howon LEE, Suwon-si (KR)

(73) Assignee: SAMSUNG ELECTRONICS CO., LTD., Suwon-si (KR)

(21) Appl. No.: 19/076,429

(22) Filed: Mar. 11, 2025

Related U.S. Application Data
(63) Continuation of application No. PCT/KR2025/001950, filed on Feb. 11, 2025.

(30) Foreign Application Priority Data
May 28, 2024 (KR) 10-2024-0069110
Jun. 28, 2024 (KR) 10-2024-0085319

(51) Int. Cl. H05K 5/02

(52) U.S. Cl. CPC H05K 5/0217

(57) ABSTRACT

A display module includes a display panel, a support plate, including a bendable region including a lattice pattern, a first region spaced from the bendable region in a first direction, and a second region between the first region and the bendable region, and an adhesive layer between the display panel and the support plate, the adhesive layer including an adhesive area and a non-adhesive area, the adhesive layer includes a first portion on the first region of the support plate, the first portion including the adhesive area; and a second portion on the second region of the support plate, the second portion including the adhesive area and the non-adhesive area, a ratio of the adhesive area of the second portion increasing along the first direction.

### CROSS-REFERENCE TO RELATED APPLICATIONS

This application is a continuation application of International Application No. PCT/KR2025/001950 designating the United States, filed on Feb. 11, 2025, in the Korean Intellectual Property Receiving Office and claiming priority to Korean Patent Application No. 10-2024-0069110, filed on May 28, 2024, and Korean Patent Application No. 10-2024-0085319, filed on Jun. 28, 2024, in the Korean Intellectual Property Office, the disclosures of which are incorporated by reference herein in their entireties.

### BACKGROUND

### 1. Field

The disclosure relates to a display module and an electronic device including the same.

### 2. Description of Related Art

With the development of display-related technology, electronic devices equipped with flexible displays are being developed recently. Flexible displays may be used not only in a flat form but also in a form deformed into a predetermined shape. For example, an electronic device including a flexible display may be implemented in a foldable form that may be unfolded or folded based on at least one folding axis.

However, the foregoing should not be construed as having been acknowledged by the applicant as a prior art to the description set forth in the disclosure, but should be construed only as a related art to the invention described herein.

### SUMMARY

There is provided a display module including: a display panel; a support plate supporting the display panel, the support plate including a bendable region including a lattice pattern, a first region spaced apart from the bendable region in a first direction, and a second region between the first region and the bendable region; and an adhesive layer between the display panel and the support plate, the adhesive layer including an adhesive area and a non-adhesive area, wherein the adhesive layer further includes: a first portion on the first region of the support plate, the first portion including the adhesive area; and a second portion on the second region of the support plate, the second portion including the adhesive area and the non-adhesive area, a ratio of the adhesive area per unit area of the second portion increasing along the first direction.

In the second portion, the adhesive area may include a plurality of geometric structures, and a size of each of the plurality of geometric structures is increased in the first direction, and the non-adhesive area may at least partially surrounds each of the plurality of geometric structures.

Each of the plurality of geometric structures may include a polygonal shape.

Each of the plurality of geometric structures may include a circular shape or an oval shape.

The adhesive area may include an adhesive material, and the non-adhesive area may include an open space.

The second portion may include an edge area provided at an end portion in a second direction perpendicular to the first direction, and the edge area has a shape in which a width of the non-adhesive area gradually decreases along the first direction.

The edge area may include a boundary line where the adhesive area and the non-adhesive area face each other, and the boundary line is curved along the first direction.

The ratio of the adhesive area per unit area of the second portion may be gradually increased from an end portion along a second direction that is perpendicular to the first direction and toward a center of the second portion.

In the second portion, the adhesive area may have a pattern shape in which a plurality of geometric structures are spaced apart from each other, the non-adhesive area may be between the plurality of geometric structures, and an interval between the plurality of geometric structures may be decreased along the first direction.

In the second portion, the adhesive area may have a pattern shape in which a plurality of geometric structures are spaced apart from each other, the non-adhesive area may be between the plurality of geometric structures, and an interval between the plurality of geometric structures may be decreased from an end portion along a second direction, perpendicular to the first direction, toward a center of the second portion.

The adhesive area may include an adhesive material, and the non-adhesive area may include the adhesive material and a non-adhesive material that covers at least one surface of the adhesive material.

The non-adhesive area of the second portion may include a first non-adhesive portion including an open space; and a second non-adhesive portion may include a non-adhesive material.

In the second portion, the non-adhesive area may include a pattern shape in which a plurality of geometric structures are arranged, and the adhesive area may surround each of the plurality of geometric structures.

The second portion may include a pattern shape in which an area of each of the plurality of geometric structures of the non-adhesive area decreases along the first direction.

There is provided a display module and a housing structure supporting the display module and configured to fold.

There is provided a display module including: a display panel; a support plate supporting the display panel, the support plate including a bendable region including a lattice pattern, a first region spaced apart from the bendable region in a first direction, and a second region between the first region and the bendable region; and an adhesive layer between the display panel and the support plate, the adhesive layer including an adhesive area and a non-adhesive area, wherein the adhesive layer further includes: a folding portion on the bendable region of the support plate and including the non-adhesive area, the non-adhesive area occupying an entirety of the folding portion; a first portion on the first region of the support plate, the first portion including the adhesive area; and a second portion on the second region of the support plate, the second portion including the non-adhesive area at end portions along a second direction perpendicular to the first direction, and the adhesive area between the end portions in the second direction.

The second portion may include an edge area, provided at the end portions along the second direction, and the edge area has a shape in which a width of the non-adhesive area is gradually decreased along the first direction.

The edge area may include a boundary line where the adhesive area and the non-adhesive area face each other, and the boundary line is curved along the first direction.

There is provided a bendable electronic device including a display module and a housing structure supporting the display module and configured to fold.

There is provided an electronic device including: a housing structure; and a display module including a plurality of bendable folding areas, coupled to the housing structure, and configured to visually expose at least a partial area thereof, wherein the display module includes: a display panel; a support plate supporting the display panel, the support plate including a bendable region including a lattice pattern and overlapping the plurality of bendable folding areas, a first region spaced apart from the bendable region in a first direction, and a second region between the first region and the bendable region; and an adhesive layer between the display panel and the support plate, the adhesive layer including an adhesive area and a non-adhesive area, wherein the adhesive layer further includes: a folding portion on the bendable region of the support plate and including the non-adhesive area, the non-adhesive area occupying an entirety of the folding portion; a first portion on the first region of the support plate, the first portion including the adhesive area; a second portion on the second region of the support plate, the second portion including the adhesive area and the non-adhesive area and having a ratio of the adhesive area per unit area of the second portion increasing from the bendable region toward the first portion; and a third portion between the plurality of bendable folding areas, the third portion including the adhesive area and the non-adhesive area and having a ratio of the adhesive area per unit area of the third portion increasing along a direction away from each of the plurality of bendable folding areas.

### BRIEF DESCRIPTION OF THE DRAWINGS

The above and other aspects, features, and advantages of certain embodiments of the present disclosure will be more apparent from the following detailed description, taken in conjunction with the accompanying drawings, in which:

FIG. 1 is a block diagram of an electronic device in a network environment according to one or more embodiments;

FIG. 2A is a view illustrating an unfolded state of an electronic device according to one or more embodiments;

FIG. 2B is a view of a folded state of an electronic device according to one or more embodiments;

FIG. 3A is a view illustrating an unfolded state of an electronic device according to one or more embodiments;

FIG. 3B is a view of a folded state of an electronic device according to one or more embodiments;

FIG. 4 is a schematic diagram illustrating a shock state of an electronic device according to one or more embodiments;

FIG. 5A is a schematic diagram of a cross section of a display module according to one or more embodiments;

FIG. 5B is a plan view of an adhesive layer according to one or more embodiments;

FIG. 6 is a plan view of an adhesive layer according to one or more embodiments;

FIG. 7A is a plan view of an adhesive layer according to one or more embodiments;

FIG. 7B is an enlarged view of an adhesive layer according to one or more embodiments;

FIG. 8A is a plan view of an adhesive layer according to one or more embodiments;

FIG. 8B is a plan view of an adhesive layer according to one or more embodiments;

FIG. 9 is a plan view of an adhesive layer according to one or more embodiments;

FIG. 10 is a plan view of an adhesive layer according to one or more embodiments;

FIG. 11 is a plan view of an adhesive layer according to one or more embodiments;

FIG. 12A is a view illustrating an unfolded state of an electronic device according to one or more embodiments;

FIG. 12B is a view of a folded state of an electronic device according to one or more embodiments;

FIG. 13A is a schematic diagram of a cross section of a display module according to one or more embodiments;

FIG. 13B is a plan view of an adhesive layer according to one or more embodiments;

FIG. 14A is a plan view of an adhesive layer according to one or more embodiments;

FIG. 14B is a plan view of an adhesive layer according to one or more embodiments;

FIG. 14C is a plan view of an adhesive layer according to one or more embodiments;

FIG. 14D is a plan view of an adhesive layer according to one or more embodiments;

FIG. 14E is a plan view of an adhesive layer according to one or more embodiments; and

FIG. 14F is a plan view of an adhesive layer according to one or more embodiments.

### DETAILED DESCRIPTION

Hereinafter, embodiments will be described in detail with reference to the accompanying drawings. When describing the embodiments with reference to the accompanying drawings, like reference numerals refer to like components, and any repeated description related thereto will be omitted.

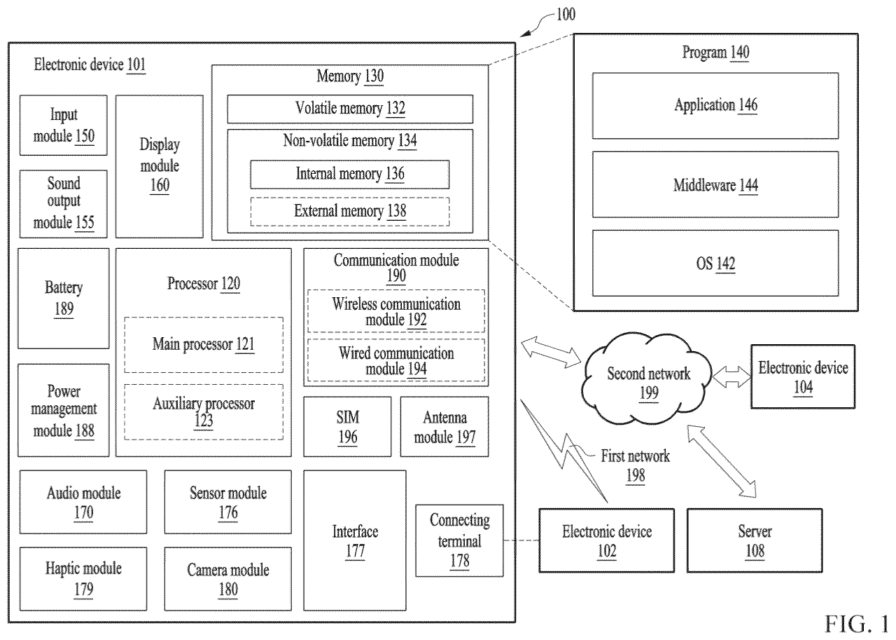

FIG. 1 is a block diagram of an electronic device 101 in a network environment 100 according to one or more embodiments.

Referring to FIG. 1, an electronic device 101 in a network environment 100 may communicate with an electronic device 102 via a first network 198 (e.g., a short-range wireless communication network), or at least one of an electronic device 104 or a server 108 via a second network 199 (e.g., a long-range wireless communication network).

In one or more embodiments, the electronic device 101 may communicate with the electronic device 104 via the server 108. In one or more embodiments, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197.

In one or more embodiments, at least one (e.g., the connecting terminal 178) of the above components may be omitted from the electronic device 101, or one or more other components may be added in the electronic device 101.

In one or more embodiments, some (e.g., the sensor module 176, the camera module 180, or the antenna module 197) of the components may be integrated as a single component (e.g., the display module 160). The processor 120 may execute, for example, software (e.g., a program 140) to control at least one other component (e.g., a hardware or software component) of the electronic device 101 coupled with the processor 120, and may perform various data processing or computation.

In one or more embodiments, as at least a portion of data processing or computation, the processor 120 may store a command or data received from another component (e.g., the sensor module 176 or the communication module 190) in a volatile memory 132, process the command or the data stored in the volatile memory 132, and store resulting data in a non-volatile memory 134. In one or more embodiments, the processor 120 may include a main processor 121 (e.g., a central processing unit (CPU) or an application processor (AP)) or an auxiliary processor 123 (e.g., a graphics processing unit (GPU), a neural processing unit (NPU), an image signal processor (ISP), a sensor hub processor, or a communication processor (CP)) that is operable independently of, or in conjunction with the main processor 121.

For example, when the electronic device 101 includes the main processor 121 and the auxiliary processor 123, the auxiliary processor 123 may be adapted to consume less power than the main processor 121 or to be specific to a specified function. The auxiliary processor 123 may be implemented as separate from, or as part of the main processor 121.

The auxiliary processor 123 may control at least some of functions or states related to at least one (e.g., the display module 160, the sensor module 176, or the communication module 190) of the components of the electronic device 101, instead of the main processor 121 while the main processor 121 is in an inactive (e.g., sleep) state, or together with the main processor 121 while the main processor 121 is an active state (e.g., executing an application). In one or more embodiments, the auxiliary processor 123 (e.g., an ISP or a CP) may be implemented as a portion of another component (e.g., the camera module 180 or the communication module 190) that is functionally related to the auxiliary processor 123.

In one or more embodiments, the auxiliary processor 123 (e.g., an NPU) may include a hardware structure specified for artificial intelligence (AI) model processing. An artificial intelligence model may be generated by machine learning. Such learning may be performed, e.g., by the electronic device 101 where the artificial intelligence is performed, or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network, or a combination of two or more thereof, but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140 and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing a record. The receiver may be used for receiving incoming calls. In one or more embodiments, the receiver may be implemented separately from the speaker or as a portion of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. In one or more embodiments, the display module 160 may include a touch sensor adapted to sense a touch, or a pressure sensor adapted to measure an intensity of a force incurred by a touch.

The audio module 170 may convert a sound into an electrical signal and vice versa. In one or more embodiments, the audio module 170 may obtain the sound via the input module 150 or output the sound via the sound output module 155 or an external electronic device (e.g., an electronic device 102 such as a speaker or a headphone) directly or wirelessly connected to the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. In one or more embodiments, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. In one or more embodiments, the interface 177 may include, for example, a high-definition multimedia interface (HDMI), a universal serial bus (USB) interface, a secure digital (SD) card interface, or an audio interface.

The connecting terminal 178 may include a connector via which the electronic device 101 may be physically connected to an external electronic device (e.g., the electronic device 102). In one or more embodiments, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or a movement) or an electrical stimulus which may be recognized by a user via his or her tactile sensation or kinesthetic sensation. In one or more embodiments, the haptic module 179 may include, for example, a motor, a piezoelectric element, or an electric stimulator.

The camera module 180 may capture a still image and moving images. In one or more embodiments, the camera module 180 may include one or more lenses, image sensors, ISPs, or flashes.

The power management module 188 may manage power supplied to the electronic device 101. In one or more embodiments, the power management module 188 may be implemented as, for example, at least a portion of a power management integrated circuit (PMIC).

The battery 189 may supply power to at least one component of the electronic device 101. In one or more embodiments, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that operate independently of the processor 120 (e.g., an application processor) and support direct (e.g., wired) communication or wireless communication. In one or more embodiments, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module, or a power line communication (PLC) module). A corresponding one of these communication modules may communicate with the external electronic device 104 via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multiple components (e.g., multiple chips) separate from each other. The wireless communication module 192 may identify and authenticate the electronic device 101 in a communication network, such as the first network 198 or the second network 199, using subscriber information (e.g., international mobile subscriber identity (IMSI)) stored in the SIM 196.

The wireless communication module 192 may support a 5G network after a 4G network, and a next-generation communication technology, e.g., a new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., a mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), an array antenna, analog beamforming, or a large scale antenna. The wireless communication module 192 may support various requirements specified in the electronic device 101, an external electronic device (e.g., the electronic device 104), or a network system (e.g., the second network 199). In one or more embodiments, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. In one or more embodiments, the antenna module 197 may include an antenna including a radiating element including a conductive material or a conductive pattern formed in or on a substrate (e.g., a printed circuit board (PCB)). In one or more embodiments, the antenna module 197 may include a plurality of antennas (e.g., array antennas). In such a case, at least one antenna appropriate for a communication scheme used in the communication network, such as the first network 198 or the second network 199, may be selected, for example, by the communication module 190 from the plurality of antennas. The signal or the power may be transmitted or received between the communication module 190 and the external electronic device via the selected at least one antenna. In one or more embodiments, another component (e.g., a radio frequency integrated circuit (RFIC)) other than the radiating element may be additionally formed as a portion of the antenna module 197.

In one or more embodiments, the antenna module 197 may form a mmWave antenna module. In one or more embodiments, the mmWave antenna module may include a PCB, an RFIC disposed on a first surface (e.g., a bottom surface) of the PCB or adjacent to the first surface and capable of supporting a designated a high-frequency band (e.g., the mm Wave band), and a plurality of antennas (e.g., array antennas) disposed on a second surface (e.g., a top or a side surface) of the PCB, or adjacent to the second surface and capable of transmitting or receiving signals in the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

In one or more embodiments, commands or data may be transmitted or received between the electronic device 101 and the external electronic device 104 via the server 108 coupled with the second network 199. Each of the external electronic devices, electronic device 102 or electronic device 104, may be a device of the same type as or a different type from the electronic device 101. In one or more embodiments, all or some of operations to be executed by the electronic device 101 may be executed at one or more of external electronic devices (e.g., the external electronic devices, electronic device 102 and electronic device 104, or the server 108). For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In one or more embodiments, the external electronic device 104 may include an Internet-of-things (IoT) device. The server 108 may be an intelligent server using machine learning and/or a neural network. In one or more embodiments, the external electronic device 104 or the server 108 may be included in the second network 199. The electronic device 101 may be applied to intelligent services (e.g., smart home, smart city, smart car, or healthcare) based on 5G communication technology or IoT-related technology.

It should be appreciated that various embodiments of the disclosure and the terms used therein are not intended to limit the technical features set forth herein to particular embodiments and include various changes, equivalents, or replacements for a corresponding embodiment. With regard to the description of the drawings, similar reference numerals may be used to refer to similar or related components. It is to be understood that a singular form of a noun corresponding to an item may include one or more of the things, unless the relevant context clearly indicates otherwise. As used herein, “A or B”, “at least one of A and B”, “at least one of A or B”, “A, B or C”, “at least one of A, B and C”, and “at least one of A, B, or C”, each of which may include any one of the items listed together in the corresponding one of the phrases, or all possible combinations thereof. Terms such as “first”, “second”, or “first” or “second” may simply be used to distinguish the component from other components in question, and do not limit the components in other aspects (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., by wire), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, in one or more embodiments, the module may be implemented in a form of an application-specific integrated circuit (ASIC).

Various embodiments may be implemented as software (e.g., the program) including one or more instructions that are stored in a storage medium (e.g., internal memory 136 or external memory 138 of FIG. 1) that is readable by a machine (e.g., an electronic device). For example, a processor of the machine (e.g., the electronic device) may invoke at least one of the one or more instructions stored in the storage medium, and execute it. This allows the machine to be operated to perform at least one function according to the at least one instruction invoked. The one or more instructions may include code generated by a compiler or code executable by an interpreter. The machine-readable storage medium may be provided in the form of a non-transitory storage medium. Here, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

In one or more embodiments, a method according to various embodiments disclosed herein may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to embodiments, one or more of the above-described components or operations may be omitted, or one or more other components or operations may be added. Alternatively or additionally, a plurality of components (e.g., modules or programs) may be integrated into a single component. In such a case, according to embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

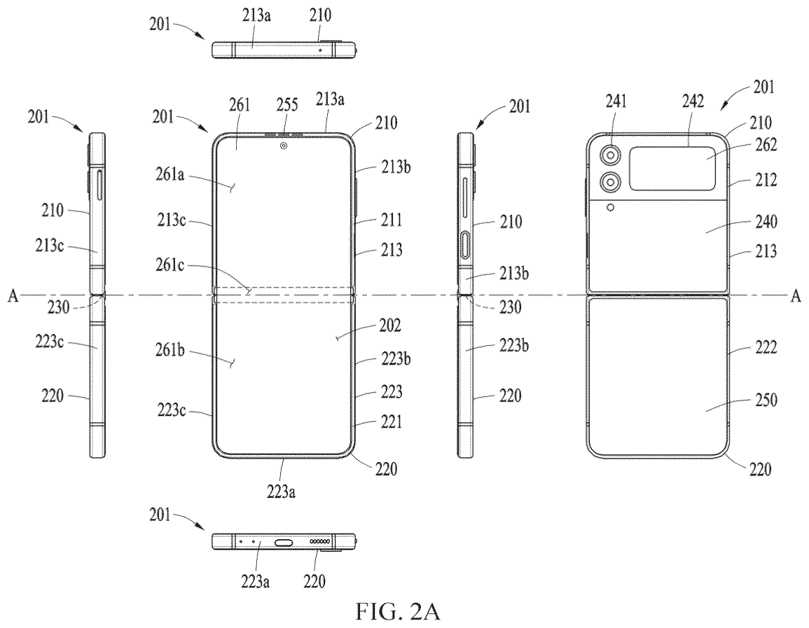

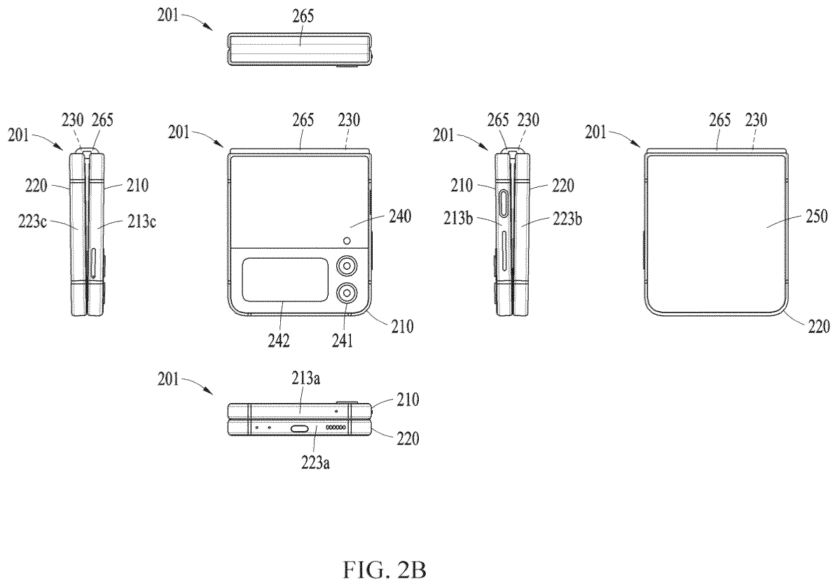

FIG. 2A is a view illustrating an unfolded state of an electronic device 201 according to one or more embodiments, and FIG. 2B is a view of a folded state of the electronic device 201 according to one or more embodiments.

Referring to FIG. 2A and FIG. 2B, an electronic device 201 (e.g., the electronic device 101 of FIG. 1) according to one or more embodiments may include housing structure 210 and housing structure 220 rotatably coupled to each other through a hinge structure to be folded with respect to each other, a hinge housing 265 for covering a bendable portion of the housing structure 210 and housing structure 220, and a display 261 (e.g., a flexible display or a foldable display) (e.g., the display module 160 of FIG. 1) disposed in a space formed by the housing structure 210 and housing structure 220.

Hereinafter, the description provided above will not be repeated, and some configurations and structures of the electronic device may be replaced, added, or omitted within a range that those skilled in the art can easily understand by referring to the following drawings and description. Additionally, the features, or at least one configuration in the embodiments described above may be combined with the electronic device unless technically obviously infeasible.

In one or more embodiments, a surface on which the display 261 is disposed may be defined as a front surface of the electronic device 201, and a surface opposite to the front surface may be defined as a rear surface of the electronic device 201. Further, a surface surrounding a space between the front surface and the rear surface may be defined as a side surface of the electronic device 201.

In one or more embodiments, the housing structure 210 and housing structure 220 may include a first housing portion 210, a second housing portion 220, a first rear cover 240, and a second rear cover 250. The housing structure 210 and housing structure 220 of the electronic device 201 are not limited to the shapes or the combination and/or coupling of components shown in FIG. 2A and FIG. 2B, and may be implemented in other shapes or by another combination and/or coupling of components.

In one or more embodiments, the first housing portion 210 and the second housing portion 220 may be disposed on both sides (e.g., an upper portion and a lower portion) with respect to a folding axis A, and may be disposed substantially symmetrically with respect to the folding axis A. In one or more embodiments, the angle or distance between the first housing portion 210 and the second housing portion 220 may vary depending on whether the electronic device 201 is in an unfolded state, a folded state, or an intermediate state.

However, the term “substantially” used herein may refer to the same level, reflecting the tolerances or errors in general manufacturing processes. Alternatively, the term “substantially” may refer to a range that includes any of the following ranges, based on 0% literally indicating the same, +/−0.1%, +/−0.5%, +/−1%, +/−3%, +/−5%, +/−7%, +/−10%, +/−15%, and +/−20%.

In one or more embodiments, the first housing portion 210 may be connected to a hinge assembly 230 in the unfolded state of the electronic device 201. The first housing portion 210 may include a first surface 211 facing the front surface of the electronic device 201, a second surface 212 facing a direction opposite to the first surface 211, and a first side portion 213 enclosing at least a portion of a space between the first surface 211 and the second surface 212. The first side member 213 may include a first side surface 213a disposed substantially in parallel with the folding axis A, a second side surface 213b extending in a direction substantially perpendicular to the folding axis A from one end of the first side surface 213a, and a third side surface 213c extending in a direction substantially perpendicular to the folding axis A from another end of the first side surface 213a and substantially parallel to the second side surface 213b.

In one or more embodiments, the second housing portion 220 may be connected to the hinge assembly 230 in the unfolded state of the electronic device 201. The second housing portion 220 may include a third surface 221 facing the front surface of the electronic device 201, a fourth surface 222 facing a direction opposite to the third surface 221, and a second side portion 223 enclosing at least a portion of a space between the third surface 221 and the fourth surface 222. The second side member 223 may include a fourth side surface 223a disposed substantially in parallel with the folding axis A, a fifth side surface 223b extending in a direction substantially perpendicular to the folding axis A from one end of the fourth side surface 223a, and a sixth side surface 223c extending in a direction substantially perpendicular to the folding axis A from another end of the fourth side surface 223a and substantially parallel to the fifth side surface 223b. The first surface 211 and the third surface 221 may face each other when the electronic device 201 is in the folded state.

In one or more embodiments, the electronic device 201 may include an accommodating portion 202 that is recessed to accommodate the display 261 through the structural coupling of the first housing portion 210 and the second housing portion 220. The accommodating portion 202 may have substantially the same size as the display 261.

In one or more embodiments, at least a portion of the first housing portion 210 and the second housing portion 220 may be formed of a metal material or a non-metal material having a predetermined magnitude of rigidity appropriate to support the display 261.

In one or more embodiments, the electronic device 201 may include a sound output module 255 (e.g., the sound output module 155) disposed through at least a partial area of the first surface 211.

In one or more embodiments, the first rear cover 240 may be disposed on the second surface 212 of the first housing portion 210, and may have a substantially rectangular periphery. At least a portion of the periphery of the first rear cover 240 may be surrounded by the first housing portion 210. The second rear cover 250 may be disposed on the fourth surface 222 of the second housing portion 220, and may have a substantially rectangular periphery. At least a portion of the periphery of the second rear cover 250 may be surrounded by the second housing portion 220.

In one or more embodiments, the first rear cover 240 and the second rear cover 250 may have substantially symmetrical shapes with respect to the folding axis A. In one or more embodiments, the first rear cover 240 and the second rear cover 250 may have different shapes. In one or more embodiments, the first housing portion 210 and the first rear cover 240 may be integrally formed, and the second housing portion 220 and the second rear cover 250 may be integrally formed.

In one or more embodiments, the first housing portion 210, the second housing portion 220, the first rear cover 240, and the second rear cover 250 may provide a space in which various components (e.g., the at least one processor 120, the antenna module 197, the sensor module 176, or the battery 189 of FIG. 1) of the electronic device 201 can be arranged through a structure in which the first housing portion 210, the second housing portion 220, the first rear cover 240, and the second rear cover 250 are coupled to one another.

In one or more embodiments, at least one component may be visually exposed on the rear surface of the electronic device 201. For example, at least one component may be visually exposed through a first rear area 241 of the first rear cover 240. Here, the component may include a proximity sensor, a rear camera module, and/or a flash. In one or more embodiments, at least a portion of a sub-display 262 may be visually exposed through a second rear area 242 of the first rear cover 240.

In one or more embodiments, the display 261 may be disposed in the accommodating portion 202 formed by the housing structure 210 and housing structure 220. For example, the display 261 may be arranged to occupy substantially most of the front surface of the electronic device 201. The front surface of the electronic device 201 may include an area in which the display 261 is disposed, and a partial area (e.g., a periphery area) of the first housing portion 210 and a partial area (e.g., a periphery area) of the second housing portion 220, which are adjacent to the display 261.

The rear surface of the electronic device 201 may include the first rear cover 240, a partial area (e.g., a periphery area) of the first housing portion 210 adjacent to the first rear cover 240, the second rear cover 250, and a partial area (e.g., a periphery area) of the second housing portion 220 adjacent to the second rear cover 250.

In one or more embodiments, at least a partial area of the display 261 may be a display that can be deformed into a planar surface or a curved surface. In one or more embodiments, the display 261 may include a folding area 261c, a first area 261a on a first side (e.g., an upper portion) of the folding area 261c, and a second area 261b on a second side (e.g., a lower portion) of the folding area 261c.

In one or more embodiments, the first area 261a may be positioned on the first surface 211 of the first housing portion 210, and the second area 261b may be positioned on the third surface 221 of the second housing portion 220. However, the area division of the display 261 is merely an example, and the display 261 may be divided into a plurality of areas depending on the structure or functions of the display 261.

For example, as shown in FIG. 2A, the display 261 may be divided into areas based on the folding axis A or the folding area 261c extending parallel to the X-axis, or the display 261 may be divided into areas based on another folding area (e.g., a folding area extending parallel to the Y-axis) or another folding axis (e.g., a folding axis parallel to the Y-axis). Such area division of the display 261 is merely a physical division based on the housing structure 210 and housing structure 220 and the hinge assembly 230, and the display 261 may display substantially one screen through the housing structure 210 and housing structure 220 and the hinge assembly 230. In one or more embodiments, the first area 261a and the second area 261b may have substantially symmetrical shapes with respect to the folding area 261c.

In one or more embodiments, the hinge housing 265 may be arranged between the first housing portion 210 and the second housing portion 220 and configured to accommodate or cover other components of the hinge assembly 230. The hinge housing 265 may be hidden by at least a portion of the first housing portion 210 and the second housing portion 220 or exposed to the outside according to the operational state of the electronic device 201.

For example, when the electronic device 201 is in an unfolded state as shown in FIG. 2A, the hinge housing 265 may be hidden by the first housing portion 210 and the second housing portion 220 and not exposed to the outside, and when the electronic device 201 is in a folded state as shown in FIG. 2B, the hinge housing 265 may be exposed to the outside between the first housing portion 210 and the second housing portion 220. Meanwhile, when the electronic device 201 is in an intermediate state in which the first housing portion 210 and the second housing portion 220 form an angle with each other, at least a portion of the hinge housing 265 may be exposed to the outside between the first housing portion 210 and the second housing portion 220. In this case, an area of the hinge housing 265 exposed to the outside may be smaller than the area of the hinge housing 265 exposed when the electronic device 201 is in the folded state. In one or more embodiments, the hinge housing 265 may have a curved surface.

Describing the operation of the electronic device 201 according to one or more embodiments, when the electronic device 201 is in an unfolded state (e.g., the state of the electronic device 201 of FIG. 2A), the first housing portion 210 and the second housing portion 220 may form a first angle (e.g., about 180 degrees) with each other, and the first area 261a and the second area 261b of the display 261 may be oriented in substantially the same direction. The folding area 261c of the display 261 may be on substantially the same plane as the first area 261a and the second area 261b.

In one or more embodiments, when the electronic device 201 is in the unfolded state, the first housing portion 210 may rotate at a second angle (e.g., about 360 degrees) relative to the second housing portion 220, whereby the first housing portion 210 and the second housing portion 220 may be reversely folded such that the second surface 212 and the fourth surface 222 may face each other. Meanwhile, when the electronic device 201 is in the folded state (e.g., the state of the electronic device 201 of FIG. 2B), the first housing portion 210 and the second housing portion 220 may face each other.

In one or more embodiments, the first housing portion 210 and the second housing portion 220 may form an angle of about 0 degrees to about 10 degrees, and the first area 261a and the second area 261b of the display 261 may face each other. At least a portion of the folding area 261c of the display 261 may be deformed into a curved surface. Meanwhile, when the electronic device 201 is in the intermediate state, the first housing portion 210 and the second housing portion 220 may form a predetermined angle with each other.

In one or more embodiments, an angle (e.g., a third angle, about 90 degrees) formed by the first area 261a and the second area 261b of the display 261 may be greater than that when the electronic device 201 is in the folded state and less than that when the electronic device 201 is in the unfolded state. At least a portion of the folding area 261c of the display 261 may be deformed into a curved surface. In this case, the curvature of the curved surface of the folding area 261c may be smaller than that when the electronic device 201 is in the folded state.

Meanwhile, the various embodiments of the electronic device described in the disclosure are not limited to the electronic device 201 described with reference to FIG. 2A and FIG. 2B, and may also apply to electronic devices with various structures, shapes, purposes, and uses.

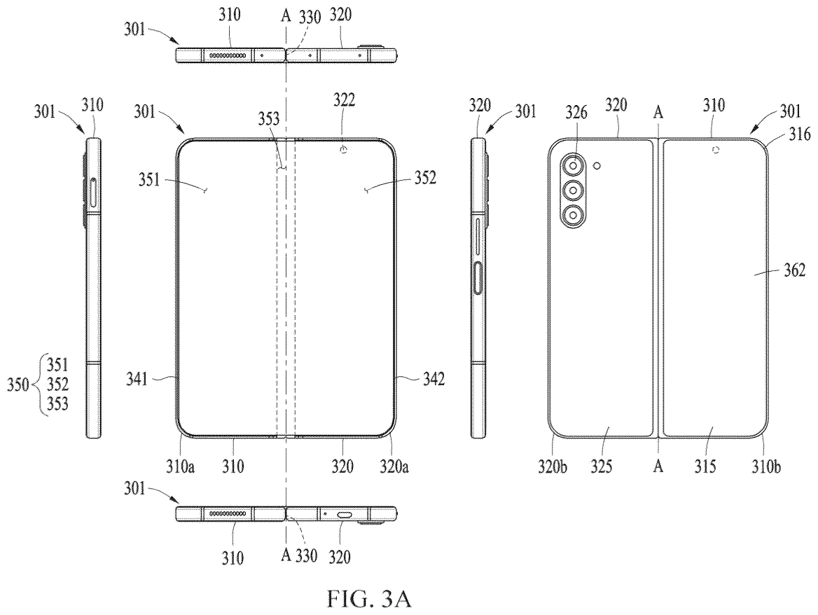

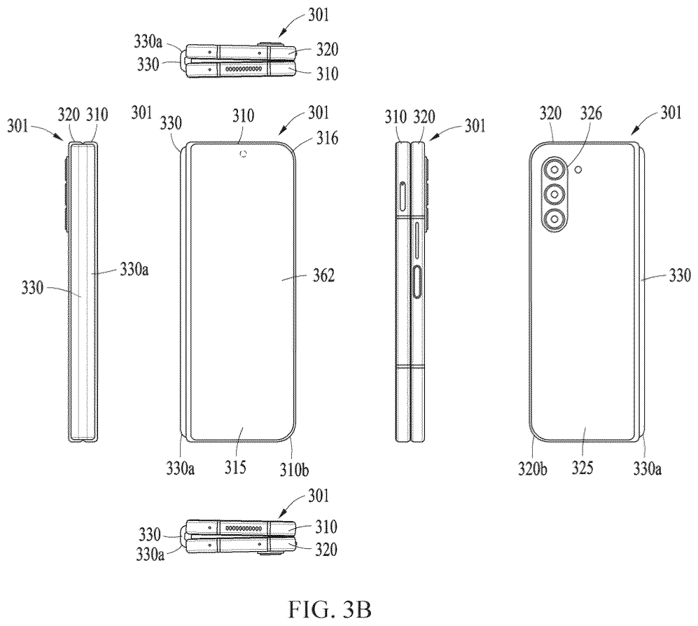

FIG. 3A is a view illustrating an unfolded state of an electronic device 301 according to one or more embodiments, and FIG. 3B is a view of a folded state of the electronic device 301 according to one or more embodiments.

Referring to FIG. 3A and FIG. 3B, an electronic device 301 (e.g., the electronic device 101 of FIG. 1) according to one or more embodiments may include housing structure 310 and housing structure 320 that form the exterior and accommodate components therein.

Hereinafter, the description provided above will not be repeated, and some configurations and structures of the electronic device 301 may be replaced, added, or omitted within a range that those skilled in the art can easily understand by referring to the following drawings and description. Additionally, the features, or at least one configuration in the embodiments described above may be combined with the electronic device 301 unless technically obviously infeasible.

In one or more embodiments, the electronic device 301 may be a bendable (or foldable) electronic device. In one or more embodiments, the electronic device 301 may include the housing structure 310 and housing structure 320 and/or a display 350 (e.g., the display module 160 of FIG. 1). The housing structure 310 and housing structure 320 may form the exterior of the electronic device 301. In one or more embodiments, the housing structure 310 and housing structure 320 may include a first housing portion 310 and a second housing portion 320.

In one or more embodiments, the display 350 may include a flexible or foldable display panel disposed in a space formed by the housing structure 310 and housing structure 320. A surface on which the display 350 is disposed (or a surface on which the display 350 is viewed from the outside of the electronic device 301) may be defined as a front surface of the electronic device 301. In addition, a surface opposite to the front surface may be defined as a rear surface of the electronic device 301. Further, a surface surrounding a space between the front surface and the rear surface may be defined as a side surface of the electronic device 301.

In one or more embodiments, the electronic device 301 may include a hinge assembly 330 foldably supporting the housing structure 310 and housing structure 320 and a hinge housing 330a covering a bendable portion of the housing structure 310 and housing structure 320. However, the housing structure 310 and housing structure 320 of the electronic device 301 are not limited to the shape and coupling shown in FIG. 3A and FIG. 3B, and may be implemented in a different shape or a different combination and/or coupling of components.

In one or more embodiments, the first housing portion 310 may be connected to the hinge assembly 330, and may include a first surface 310a facing a first direction and a second surface 310b facing a second direction opposite to the first direction. The second housing portion 320 is connected to the hinge assembly 330 and may include a third surface 320a facing a third direction and a fourth surface 320b facing a fourth direction opposite to the third direction. The second housing portion 320 may rotate relative to the first housing portion 310 about the hinge assembly 330. The electronic device 301 may change to a folded state or an unfolded state.

In one or more embodiments, the first surface 310a may face the third surface 320a in a state in which the electronic device 301 is fully folded, and the third direction may be substantially the same as the first direction in a state in which the electronic device 301 is fully unfolded.

In one or more embodiments, the first housing portion 310 and the second housing portion 320 may be foldably connected to each other. The first housing portion 310 and the second housing portion 320 may be disposed on both sides of a folding axis A and have generally symmetrical shapes with respect to the folding axis A.

In one or more embodiments, the angle or distance between the first housing portion 310 and the second housing portion 320 may vary according to whether the state of the electronic device 301 is the unfolded state, the folded state, or a partially unfolded (or partially folded) intermediate state.

According to one or more embodiments, the second housing portion 320 may include a sensor area 322 in which various sensors are arranged. For example, various sensors may be positioned on the rear surface of the display 350 in the sensor area 322. According to one or more embodiments, the first housing portion 310 may also include a sensor area in which at least one sensor is arranged.

In one or more embodiments, the first housing portion 310 and the second housing portion 320 may form a recess to accommodate the display 350. In one or more embodiments, components embedded in the electronic device 301 to perform various functions may be exposed to the front surface of the electronic device 301 through the sensor area 322 or through one or more openings provided in the sensor area 322. In one or more embodiments, the components may include various types of sensors. The sensors may include, for example, at least one of a front camera or a proximity sensor. In one or more embodiments, the sensor area 322 may not be included in the second housing portion 320 or may be formed at a position different from that shown in the drawings.

In one or more embodiments, at least a portion of the first housing portion 310 and the second housing portion 320 may be formed of a metal material or a non-metal material having a selected magnitude of rigidity to support the display 350.

For example, at least a portion formed of the metal material may provide a ground of the electronic device 301, and may be electrically connected to a ground formed on a PCB disposed inside the housing structure 310 and housing structure 320.

In one or more embodiments, the first housing portion 310 may include a first rear cover 315 and a first side area 341. The first rear cover 315 may be coupled to the first side area 341. For example, the first rear cover 315 may have a substantially rectangular periphery, the periphery of which may be surrounded by the first side area 341.

In one or more embodiments, the second housing portion 320 may include a second rear cover 325 and a second side area 342. The second rear cover 325 may be coupled to the second side area 342. For example, the periphery of the second rear cover 325 may be surrounded by the second side area 342.

In one or more embodiments, the first rear cover 315 and the second rear cover 325 may have substantially symmetrical shapes with respect to the folding axis A. However, the first rear cover 315 and the second rear cover 325 are not necessarily mutually symmetrical, and in one or more embodiments, the electronic device 301 may include the first rear cover 315 and the second rear cover 325 having various shapes. In one or more embodiments, the first rear cover 315 may be formed integrally with the first side area 341, and the second rear cover 325 may be formed integrally with the second side area 342.

In one or more embodiments, the first housing portion 310 and the second housing portion 320 may form a space in which various components (e.g., the at least one processor 120, the antenna module 197, the sensor module 176, or the battery 189 of FIG. 1) of the electronic device 301 can be arranged. According to one or more embodiments, one or more components may be disposed or visually exposed on the rear surface of the electronic device 301.

For example, at least a portion of a sub-display 362 may be visually exposed through a first rear area 316 of the first rear cover 315. In one or more embodiments, one or more components or sensors may be visually exposed through a second rear area 326 of the second rear cover 325. In one or more embodiments, the sensors may include a proximity sensor and/or a rear camera.

In one or more embodiments, a front camera visually exposed to the front surface of the electronic device 301 through one or more openings provided in the sensor area 322, or a rear camera visually exposed through the second rear area 326 of the second rear cover 325 may include one or more lenses, an image sensor, and/or an ISP. A flash may include, for example, a light-emitting diode (LED) or a xenon lamp. In some embodiments, two or more lenses (IR cameras, wide angle and telephoto lenses) and image sensors may be disposed on one surface of the electronic device 301.

In one or more embodiments, referring to FIG. 3B, the hinge housing 330a may be disposed between the first housing portion 310 and the second housing portion 320 to cover internal components (e.g., the hinge assembly 330). According to one or more embodiments, the hinge assembly 330 may be covered by a portion of the first housing portion 310 and the second housing portion 320, or may be exposed to the outside, depending on the state of the electronic device 301 (e.g., the unfolded state, the intermediate state, or the folded state).

In one or more embodiments, when the electronic device 301 is in the unfolded state (e.g., the fully unfolded state) as illustrated in FIG. 3A, the hinge assembly 330 may be covered by the first housing portion 310 and the second housing portion 320 not to be substantially exposed.

In one or more embodiments, when the electronic device 301 is in the folded state (e.g., the fully folded state) as illustrated in FIG. 3B, the hinge assembly 330 may be exposed to the outside between the first housing portion 310 and the second housing portion 320.

In one or more embodiments, in the intermediate state in which the first housing portion 310 and the second housing portion 320 are folded with a certain angle, the hinge assembly 330 may be partially exposed to the outside between the first housing portion 310 and the second housing portion 320. However, the area exposed in this case may be smaller than that in the fully folded state. In one or more embodiments, the hinge assembly 330 may have a curved surface.

In one or more embodiments, the first side area 341 and the second side area 342 may be formed to surround at least a portion of an edge region of the display 350. For example, the first side area 341 and the second side area 342 may surround the front surface and/or the side surface of the edge region of the display 350. In one or more embodiments, the first side area 341 and the second side area 342 may be formed to surround at least a portion of an edge region of the display 350.

In one or more embodiments, the display 350 may be disposed in the space formed by the housing structure 310 and housing structure 320. For example, the display 350 may be seated on the recess formed by the housing structure 310 and housing structure 320, and may be viewed from the outside through the front surface of the electronic device 301. For example, the display 350 may form most of the front surface of the electronic device 301. For example, the front surface of the electronic device 301 may include the display 350, and a partial area of the first housing portion 310 and a partial area of the second housing portion 320, which are adjacent to the display 350. For example, the rear surface of the electronic device 301 may include the first rear cover 315, a partial area of the first housing portion 310 adjacent to the first rear cover 315, the second rear cover 325, and a partial area of the second housing portion 320 adjacent to the second rear cover 325.

In one or more embodiments, the display 350 may be a display with at least a partial area that can be deformed into a planar surface or a curved surface. According to one or more embodiments, the display 350 may include a folding area 353, a first area 351 disposed on one side of the folding area 353 (e.g., on the left side of the folding area 353 shown in FIG. 3A), and a second area 352 disposed on the other side of the folding area 353 (e.g., on the right side of the folding area 353 shown in FIG. 3A). However, such an area division of the display 350 shown in FIG. 3A is merely an example, and the display 350 may be divided into a plurality of areas (e.g., four or more areas, or two areas) depending on a structure or functions thereof. For example, in the embodiment shown in FIG. 3A, the display 350 may be divided into areas based on the folding area 353 extending in parallel to the folding axis A. However, in one or more embodiments, the display 350 may be divided into areas based on another folding axis (e.g., a folding axis parallel to a width direction of the electronic device).

In one or more embodiments, the display 350 may be coupled to or disposed adjacent to a touch panel in which a touch sensing circuit and a pressure sensor configured to measure an intensity (or pressure) of a touch are provided. For example, the display 350 is an example of a touch panel, and may be coupled to or disposed adjacent to a touch panel for detecting an electromagnetic resonance (EMR) type stylus pen.

In one or more embodiments, the first area 351 and the second area 352 may have generally symmetrical shapes with respect to the folding area 353. However, unlike the first area 351, the second area 352 may include a notch that is cut depending on the presence of the sensor area 322, but may be symmetrical to the first area 351 in the other areas. For example, the first area 351 and the second area 352 may include mutually symmetrical portions and mutually asymmetrical portions.

In one or more embodiments, the edge thicknesses of the first area 351 and the second area 352 may be different from the edge thickness of the folding area 353. The edge thickness of the folding area 353 may be less than those of the first area 351 and the second area 352. The first area 351 and the second area 352 may be asymmetrical in terms of thickness when the first area 351 and the second area 352 are cross-sectionally viewed.

For example, an edge of the first area 351 may be formed to have a first radius of curvature, and an edge of the second area 352 may be formed to have a second radius of curvature different from the first radius of curvature. In one or more embodiments, the first area 351 and the second area 352 may be symmetrical in terms of thickness when the first area 351 and the second area 352 are cross-sectionally viewed.

Hereinafter, each area of the display 350, and operations of the first housing portion 310 and the second housing portion 320 depending on the state (e.g., the folded state, the unfolded state, or the intermediate state) of the electronic device 301 will be described.

In one or more embodiments, when the electronic device 301 is in the unfolded state (e.g., FIG. 3A), the first surface 310a of the first housing portion 310 and the third surface 320a of the second housing portion 320 may be arranged to face the same direction while forming an angle of 180 degrees. The surface of the first area 351 of the display 350 and the surface of the second area 352 thereof may face the same direction (e.g., the front direction of the electronic device) while forming 180 degrees. The folding area 353 may form the same plane in conjunction with the first area 351 and the second area 352.

In one or more embodiments, when the electronic device 301 is in the folded state (e.g., FIG. 3B), the first surface 310a of the first housing portion 310 and the third surface 320a of the second housing portion 320 may be arranged to face each other. The surface of the first area 351 of the display 350 and the surface of the second area 352 thereof may face each other while forming a narrow angle (e.g., between 0 degrees to 10 degrees). At least a portion of the folding area 353 may change to a curved surface having a predetermined curvature.

In one or more embodiments, when the electronic device 301 is in the intermediate state, the first housing portion 310 and the second housing portion 320 may be arranged with a certain angle. The surface of the first area 351 of the display 350 and the surface of the second area 352 thereof may form an angle greater than that in the folded state and smaller than that in the unfolded state. At least a portion of the folding area 353 may change to a curved surface having a predetermined curvature, and the curvature may be smaller than that in the folded state.

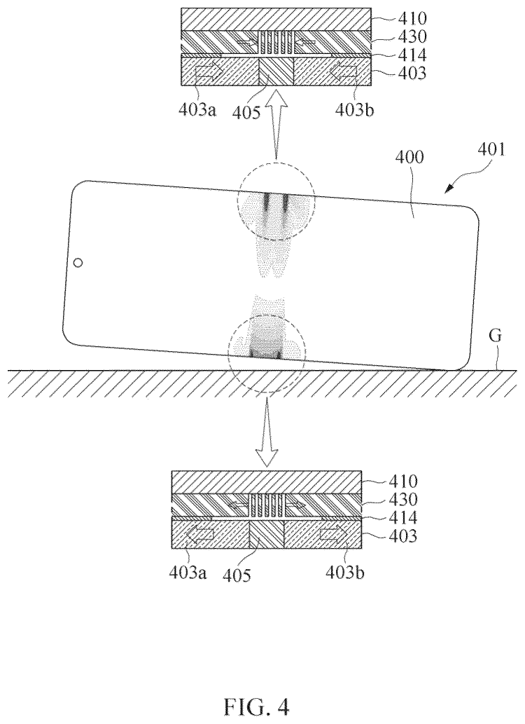

FIG. 4 is a schematic diagram illustrating a shock state of an electronic device 401 according to one or more embodiments.

Referring to FIG. 4, an electronic device 401 (e.g., the electronic device 101 of FIG. 1, the electronic device 201 of FIG. 2A and FIG. 2B, or the electronic device 301 of FIG. 3A and FIG. 3B) according to one or more embodiments may include at least one of a housing structure 403 (e.g., the housing structure 210 and housing structure 220 of FIG. 2A and FIG. 2B, or the housing structure 310 and housing structure 320 of FIG. 3A and FIG. 3B) and a display module 400 (e.g., the display module 160 of FIG. 1, the display 261 of FIG. 2A and FIG. 2B, or the display 350 of FIG. 3A and FIG. 3B).

Hereinafter, the description provided above will not be repeated, and some configurations and structures of the electronic device 401 may be replaced, added, or omitted within a range that those skilled in the art can easily understand by referring to the following drawings and description. Additionally, the features, or at least one configuration in the embodiments described above may be combined with the electronic device 401 unless technically obviously infeasible.

In one or more embodiments, the electronic device 401 may be a bendable (or foldable) electronic device. The electronic device 401 may include the housing structure 403 and the display module 400 supported by the housing structure 403.

In one or more embodiments, the housing structure 403 may include a first housing portion 403a (e.g., the first housing portion 210 of FIG. 2A and FIG. 2B or the first housing portion 310 of FIG. 3A and FIG. 3B) and a second housing portion 403b (e.g., the second housing portion 220 of FIG. 2A and FIG. 2B or the second housing portion 320 of FIG. 3A and FIG. 3B).

In one or more embodiments, the first housing portion 403a and the second housing portion 403b may be rotatably coupled so as to be bent with respect to each other. A hinge housing 405 (e.g., the hinge housing 265 of FIG. 2A and FIG. 2B or the hinge housing 330a of FIG. 3A and FIG. 3B) may be provided between the first housing portion 403a and the second housing portion 403b.

In one or more embodiments, the display module 400 may be a flexible, foldable, or bendable display. The display module 400 and the housing structure 403 may be connected by an adhesive member 414.

In one or more embodiments, the display module 400 may include a display panel 410 and a support plate 430. However, the cross-section of FIG. 4 illustrates only some of the components of the display module 400, and the display module 400 may further include a plurality of components in addition to the display panel 410 and the support plate 430.

As shown in FIG. 4, when the electronic device 401 is dropped or a shock is applied to the electronic device 401 while the electronic device 401 is in the unfolded state, a force may be applied to at least one of the first housing portion 403a and the second housing portion 403b in a direction away from or toward the hinge housing 405.

In one or more embodiments, when at least one of the first housing portion 403a and the second housing portion 403b temporarily moves in a direction relatively far away from or close to the hinge housing 405, the display module 400 may be stretched or compressed. For example, if the support plate 430 is stretched or compressed, the display panel 410 may be bent, stressed, or damaged.

Hereinafter, the display module 400 according to various embodiments of the present disclosure will be described, wherein the display module 400 may reduce or disperse the force transmitted from the support plate 430 to the display panel 410, thereby reducing or preventing the display panel 410 from being bent or damaged.

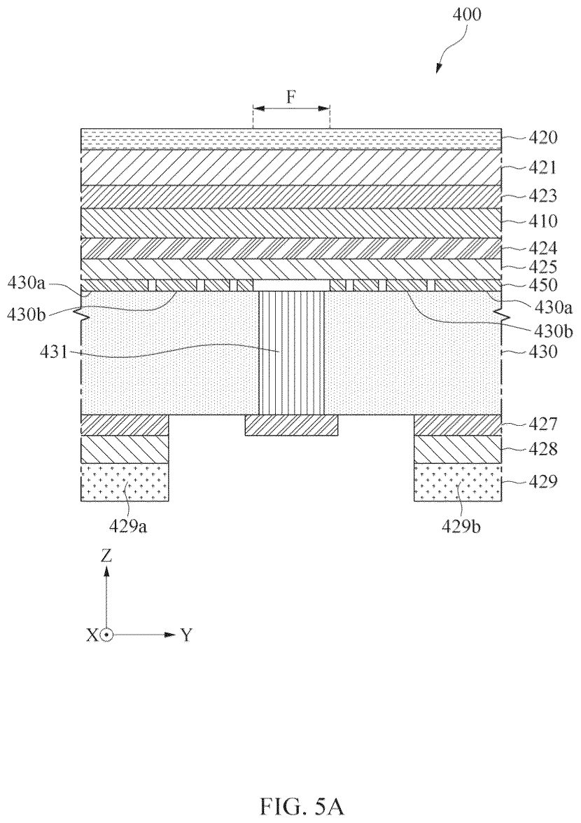

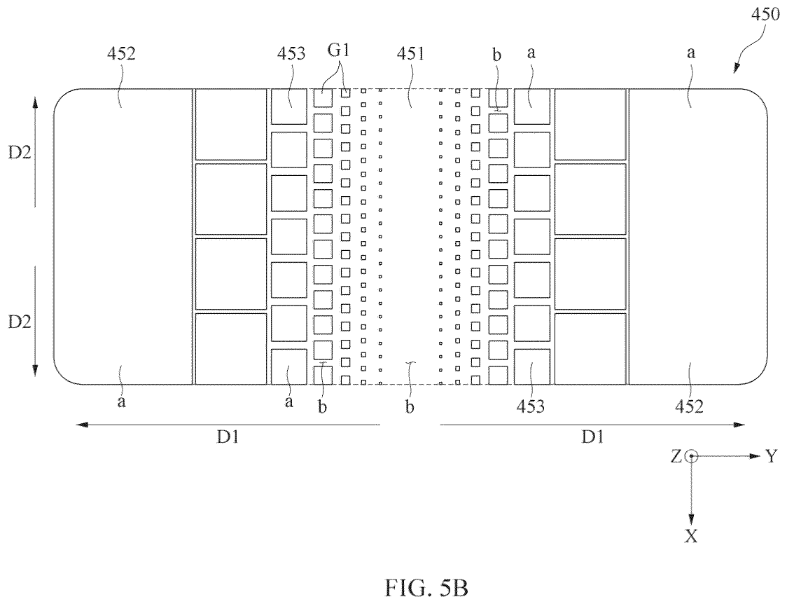

FIG. 5A is a schematic diagram of a cross section of a display module 400 according to one or more embodiments, and FIG. 5B is a plan view of the adhesive layer 450 according to one or more embodiments.

Referring to FIG. 5A and FIG. 5B, a display module 400 according to one or more embodiments may include at least a portion of a display panel 410, a foldable glass 420, a polarizer 423 (e.g., a polarizing film), a polymer layer 425, a shield layer 427, a reinforcement plate 429, and a support plate 430.

Hereinafter, the description provided above will not be repeated, and some configurations and structures of the display module 400 may be replaced, added, or omitted within a range that those skilled in the art can easily understand by referring to the following drawings and description. Additionally, the features, or at least one configuration in the embodiments described above may be combined with the display module 400 unless technically obviously infeasible.

In one or more embodiments, the display module 400 may include a bendable folding area F (e.g., the folding area 261c of FIG. 2A or the folding area 353 of FIG. 3A). The display module 400 may be bent so that the areas on both sides (e.g., the +Y side and the −Y side) may face each other based on the folding area 353.

In one or more embodiments, the display module 400 may implement a display of a foldable type that is bendable, a rollable type with a variable display area, a slidable type, or an extensible type.

In one or more embodiments, the foldable glass 420 may support and protect the display module 400. For example, the foldable glass 420 may include a plurality of bridges disposed in an area corresponding to a folding area 411 of the display module 400. For example, the plurality of bridges may provide improved flexibility to the display module 400, assist in the bending motion of the foldable glass 420, and reinforce the rigidity of the display module 400.

In one or more embodiments, the polarizer 423 may selectively transmit light that is generated from a light source of the display panel 410 and vibrates in a predetermined direction. According to one or more embodiments, the polarizer 423 may be formed integrally with the display panel 410.

In one or more embodiments, the display panel 410 may include a plurality of pixels and a wiring structure (e.g., an electrode pattern). The display panel 410 may be a foldable display panel with at least a partial area that is foldable. The display panel 410 may be supported by at least one layer (e.g., the support plate 430 and the reinforcement plate 429).

In one or more embodiments, the polymer layer 425 may be disposed under the display panel 410 (e.g., in the −Z direction). The polymer layer 425 may provide a dark background to ensure the visibility of the display panel 410. In another example, the polymer layer 425 may be formed of a buffering material to cushion the shock transmitted to the display module 400.

In one or more embodiments, to waterproof the display module 400, the polymer layer 425 may be omitted, or the polymer layer 425 may be disposed under the support plate 430. In one or more embodiments, the support plate 430 may be formed in a shape providing flexibility to the display module 400.

In one or more embodiments, the support plate 430 may be a metal layer. For example, the support plate 430 may include at least one of steel use stainless (SUS) (e.g., stainless steel (STS)), Cu, Al, or metal CLAD (e.g., a stacked member in which SUS and Al are alternately disposed), or the support plate 430 may include other alloy materials. The support plate 430 may be a metal layer.

In one or more embodiments, the support plate 430 may help to reinforce the rigidity of the display module 400, shield ambient noise, or disperse heat emitted from heat dissipating components around.

In one or more embodiments, the support plate 430 may include a lattice pattern 431. The lattice pattern 431 may be provided at a position corresponding to the folding area F. In one or more embodiments, the lattice pattern 431 may include a plurality of lattice holes and a plurality of bridges between the plurality of lattice holes. The lattice pattern 431 may increase the flexibility and durability of the support plate 430.

In one or more embodiments, the support plate 430 may include a bendable region including the lattice pattern 431. For example, the bendable region of the support plate 430 may be an area corresponding to the lattice pattern 431, or may refer to the lattice pattern 431 and a partial area adjacent thereto.

In one or more embodiments, the support plate 430 may include a first region 430a and a second region 430b. The first region 430a may be a region spaced apart from the bendable region in a first direction D1. The second region 430b may be a region between the first region 430a and the bendable region.

The support plate 430 in one or more embodiments may help to smoothly perform the folding motion of the display module 400, and help to reinforce the rigidity of the display panel 410 and the display module 400.

In one or more embodiments, the display module 400 may further include at least one functional member disposed between the polymer layer 425 and the support plate 430, or under the support plate 430. For example, the functional member may include a graphite sheet for heat dissipation, a force-touch flexible printed circuit board (FPCB), a fingerprint sensor FPCB, an antenna radiator for communication, or a conductive/non-conductive tape.

In one or more embodiments, the shield layer 427 may include an elastic material (e.g., thermoplastic polyurethane (TPU)). The shield layer 427 may be disposed under the support plate 430. The shield layer 427 may cushion the shock transmitted to the support plate 430.

In one or more embodiments, the reinforcement plate 429 may include a first reinforcement area 429a facing a first housing portion (e.g., the first housing portion 403a of FIG. 4) and a second reinforcement area 429b facing a second housing portion (e.g., the second housing portion 403b of FIG. 4).

In one or more embodiments, the display module 400 may have some of the plurality of layers described above bonded together by at least some of adhesives, adhesive 421, adhesive 424, and adhesive 428, and an adhesive layer 450.

In one or more embodiments, the adhesives, first adhesive 421, second adhesive 424, and third adhesive 428, and the adhesive layer 450 may include at least one of an optical clear adhesive (OCA), a pressure sensitive adhesive (PSA), a heat-reactive adhesive, a general adhesive, or a double-sided tape.

In one or more embodiments, the adhesives, first adhesive 421, second adhesive 424, and third adhesive 428, and the adhesive layer 450 may be formed of substantially the same material, or at least some thereof may be formed of different materials.

In one or more embodiments, the adhesives, adhesive 421, adhesive 424, and adhesive 428, may include a first adhesive 421, a second adhesive 424, and a third adhesive 428. In one or more embodiments, the first adhesive 421 may bond the foldable glass 420 and the polarizer 423. In one or more embodiments, the second adhesive 424 may bond the display panel 410 and the polymer layer 425. In one or more embodiments, the third adhesive 428 may bond the shield layer 427 and the reinforcement plate 429.

In one or more embodiments, the adhesive layer 450 may be disposed between the display panel 410 and the support plate 430. For example, the adhesive layer 450 may bond the polymer layer 425 and the support plate 430.

In one or more embodiments, the adhesive layer 450 may include an adhesive area a and a non-adhesive area b. The adhesive area a may be an area that bonds neighboring components. The non-adhesive area b may be an area that does not bond neighboring components. In another example, the non-adhesive area b may be a weak-adhesion area a that has a weaker adhesive strength than the adhesive area a.

For example, the adhesive area a may bond the polymer layer 425 (or the display panel 410) and the support plate 430. For example, the non-adhesive area b may not be bonded, or weakly bonded, to at least one of the polymer layer 425 (or the display panel 410) and the support plate 430.

In one or more embodiments, the adhesive layer 450 may bond neighboring components through the adhesive area a. Additionally, the adhesive layer 450 may reduce the movement constraints of neighboring components through the non-adhesive area b.

In one or more embodiments, the adhesive layer 450 may include a folding portion 451, a first portion 452, and a second portion 453.

In one or more embodiments, the folding portion 451 may be an area that at least partially overlaps the folding area F in a direction facing the display module 400 or the display panel 410 (e.g., the −Z direction). In another example, the folding portion 451 may be an area facing the folding area F. In another example, the folding portion 451 may be an area corresponding to the lattice pattern 431.

In one or more embodiments, the adhesive area a of the adhesive layer 450 may be omitted from folding portion 451 on the bendable region of the support plate 430.

For example, in a state in which the electronic device 401 is unfolded, the folding portion 451 may be an area that overlaps at least partly with the folding area F when viewed in a direction perpendicular to the folding area F (e.g., the Z direction). In another example, the folding portion 451 may include the non-adhesive area b. For example, the non-adhesive area b may occupy an entirety of the folding portion 451.

In one or more embodiments, the first portion 452 may be spaced apart from the folding portion 451 in a first direction D1 (e.g., the Y-axis direction). In one or more embodiments, the first direction D1 may be a direction perpendicular to the folding axis (e.g., the X-axis). For example, the first direction D1 may be a direction perpendicular to the folding axis (e.g., the X-axis) and away from the folding axis (e.g., the X-axis). A second direction D2 may be a direction perpendicular to the first direction D1 or the folding axis direction. For example, the second direction D2 may be a direction away from an imaginary line that crosses the center of the folding axis and is perpendicular to the folding axis direction (e.g., the X-axis direction).

For example, the first portion 452 may be an end portion of the adhesive layer 450 in the first direction D1 which is a side direction perpendicular to the folding axis. In another example, the first portion 452 may be a partial area between the folding portion 451 and an end portion of the adhesive layer 450 in the first direction D1. In another example, the first portion 452 may be an area disposed on the first region 430a of the support plate 430.

In one or more embodiments, the first portion 452 may include the adhesive area a. In another example, the first portion 452 may be a portion of the adhesive layer 450 including only the adhesive area a in the second direction D2. The first portion 452 may bond neighboring components.

In one or more embodiments, the second portion 453 may be disposed between the folding portion 451 and the first portion 452. In another example, the second portion 453 may be an area disposed on the second region 430b of the support plate 430. The second portion 453 may be an area including a combination of the adhesive area a and the non-adhesive area b.

In one or more embodiments, the second portion 453 may have a ratio of the adhesive area a per unit area increasing in the first direction D1. For example, the second portion 453 may have a relative ratio of the adhesive area a to the non-adhesive area b per unit area increasing in the first direction D1.

For example, the unit area may be based on the width in the first direction D1. In another example, the unit area may be based on the width of one of single-pattern structures (e.g., one geometric structure G1) in the first direction D1. In another example, the unit area may be based on the width of the largest geometric structure G1 in the first direction D1. In another example, the unit area may be based on the width of the smallest geometric structure G1 in the first direction D1. In another example, the unit area may be based on the average width of a plurality of geometric structures G1 in the first direction D1. In another example, the unit area may be based on an interval between geometric structures G1 in the first direction D1. In another example, the unit area may be based on the average interval between geometric structures G1 in the first direction D1.

However, the basis of “unit area” according to one or more embodiments of the present disclosure is not limited to the examples described above, and may be set based on the shape of the adhesive layer 450, the shape of the pattern structure, and/or the structure. Alternatively, the “relative ratio of the adhesive area a to the non-adhesive area b per unit area” may refer to the tendency of the ratio change in the second portion 453 observed in the first direction D1. For example, the second portion 453 may have a tendency for the ratio of the adhesive area a to increase in the first direction D1.

For example, from the folding portion 451 toward the first portion 452, the area occupied by the adhesive area a in the second portion 453 may gradually increase, in at least a partial area.

In one or more embodiments of the present disclosure, by changing the ratio of the adhesive area a of the second portion 453, the display module 400 may disperse stress applied to the display panel 410 or alleviate stress transmitted to the display panel 410. The adhesive layer 450 may disperse stress transmitted to the display panel 410 when the display module 400 is dropped or receives a shock so that the stress may not be concentrated, thereby reducing or preventing damage to the display module 400.

In one or more embodiments, since the adhesive layer 450 is disposed to face the support plate 430, a non-adhesive area b may be required in the area overlapping the lattice pattern 431. In the area where the adhesive area a and the non-adhesive area b adjoin, stress transmitted to the display panel 410 may be concentrated. The second portion 453 may include a combination of the adhesive area a and the non-adhesive area b, and may disperse the concentrated stress.

For example, if the second portion 453 is omitted, stress transmitted to the display panel 410 may be concentrated at the contact point between the folding portion 451 and the first portion 452, causing pressure to be applied to or damage to the display panel 410.

In one or more embodiments of the present disclosure, the second portion 453 may disperse the stress concentrated at the connection site of the folding portion 451 and the first portion 452 to a wide range, and may alleviate the stress applied to the display panel 410.

In addition, the display module 400 according to one or more embodiments of the present disclosure may reduce or prevent the loss of adhesive strength of the adhesive layer 450 and efficiently disperse stress by gradually increasing the ratio of the adhesive area a of the second portion 453 in the first direction D1.

Hereinafter, the structure and shape of the adhesive layer 450 will be described with reference to FIG. 5A and FIG. 5B, but this is only one implementation example, and the structure and shape of the adhesive layer 450 according to one or more embodiments of the present disclosure are not limited thereto.

In one or more embodiments, the adhesive area a may include an adhesive material, and the non-adhesive area b may include an open space. The non-adhesive area b including an open space may provide flexibility in the folding area F of the display module 400. In addition, the non-adhesive area b does not include a separate material, which may thus be advantageous in manufacturing the adhesive layer 450.

In one or more embodiments, the adhesive area a of the second portion 453 may be formed in a pattern shape in which a plurality of geometric structures G1 are arranged. The non-adhesive area b of the second portion 453 may be formed in a shape surrounding each of the plurality of geometric structures G1. For example, as shown in FIG. 5B, each of the plurality of geometric structures G1 may have a polygonal shape such as a quadrangular shape.

In one or more embodiments, the plurality of geometric structures G1 may be arranged to be spaced apart from each other, and the non-adhesive area b may be formed as a spaced area between the plurality of geometric structures G1. However, embodiments are not limited thereto, and at least some of the plurality of geometric structures G1 may be partially connected or continuous.

In one or more embodiments, the pattern shape of the adhesive area a of the second portion 453 may be a shape in which a plurality of geometric structures G1 of different sizes and shapes are arranged in the first direction D1. For example, the second portion 453 may have a pattern shape in which the area of each of the plurality of geometric structures G1 increases in the first direction D1.

In one or more embodiments, the pattern shape of the adhesive area a of the second portion 453 may be a shape in which a plurality of geometric structures G1 of substantially the same size and shape are arranged in a second direction D2 perpendicular to the first direction D1.

However, the term “substantially” used herein may refer to the same level, reflecting the tolerances or errors in typical manufacturing processes. Alternatively, the term “substantially” may refer to a range that includes any of the following ranges, based on 0% literally indicating the same, +/−0.1%, +/−0.5%, +/−1%, +/−3%, +/−5%, +/−7%, +/−10%, +/−15%, and +/−20%.

In one or more embodiments of the present disclosure, the adhesive layer 450 may have, through the pattern shape of the second portion 453, a ratio of the non-adhesive area b per unit area decreasing in the first direction D1 and a ratio of the adhesive area a increasing in the first direction D1.

In one or more embodiments, the pattern shape of the adhesive area a of the second portion 453 may have an interval between the plurality of geometric structures G1 gradually decreasing in the first direction D1. As the plurality of geometric structures G1 are arranged to be gradually closer in the first direction D1, the ratio of the non-adhesive area b per unit area may decrease in the first direction D1, and the ratio of the adhesive area a may increase in the first direction D1.

However, the above-described pattern shape is merely an example, and in one or more embodiments of the present disclosure, the ratio of the adhesive area a per unit area of the adhesive layer 450 may be changed in various manners through the design of the pattern shape of the second portion 453.

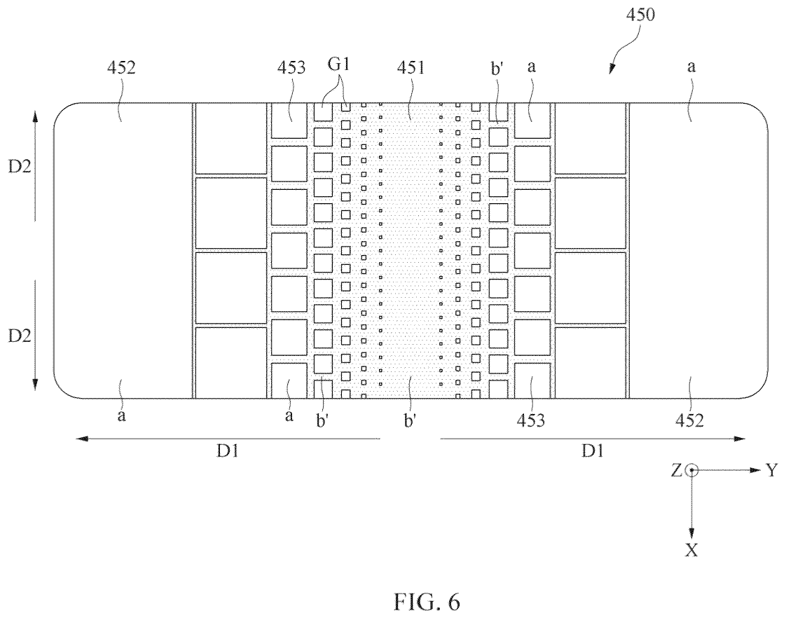

FIG. 6 is a plan view of an adhesive layer 450 according to one or more embodiments.

Referring to FIG. 6, a non-adhesive area b′ of the adhesive layer 450 according to one or more embodiments may include a non-adhesive material.

Hereinafter, the description provided above will not be repeated, and some configurations and structures of the adhesive layer 450 may be replaced, added, or omitted within a range that those skilled in the art can easily understand by referring to the following drawings and description. Additionally, the features, or at least one configuration in the embodiments described above may be combined with the adhesive layer 450 unless technically obviously infeasible.

Further, the adhesive layer 450 including the non-adhesive area b′ of FIG. 6 may be an example for implementing the non-adhesive area b or non-adhesive area b′ of the adhesive layer 450 according to one or more embodiments of the present disclosure. In addition, the adhesive layer 450 including the non-adhesive area b′ may be applied as a substitute for the non-adhesive area b of the adhesive layer 450 including the non-adhesive area b described above and described below, or in combination with the non-adhesive area b.

In one or more embodiments, the non-adhesive area b′ may include a non-adhesive material. The non-adhesive material may be a material having relatively low or substantially no adhesiveness compared to the adhesive material of the adhesive area a.

For example, the adhesive area a may include an adhesive material, and the non-adhesive area b′ may include an adhesive material and a non-adhesive material that covers at least one surface of the adhesive material.

In one or more embodiments, the non-adhesive area b′ may include an adhesive material and a non-adhesive material. For example, in the non-adhesive area b′, the non-adhesive material may be masked over the adhesive material. For example, the adhesive layer 450 may include an adhesive material of a single body, and the non-adhesive area may be implemented by patterning at least one surface of the adhesive material with the non-adhesive material.

In one or more embodiments of the present disclosure, the adhesive layer 450 may reduce or eliminate empty space through the non-adhesive area b′ including a non-adhesive material. In another example, the non-adhesive material may include an elastic body to absorb a shock transmitted from the outside. In another example, the adhesive layer 450 may be efficiently formed by patterning the non-adhesive area b′ by masking the non-adhesive material on the adhesive material.

Hereinafter, a non-adhesive area (e.g., the non-adhesive area b of FIG. 5B) formed as an open space in the adhesive layer 450 according to one or more embodiments is illustrated and described, but this is merely an example, and a non-adhesive area b′ including a non-adhesive material may be applied to the adhesive layer 450 including the non-adhesive area b′, in at least a partial area.

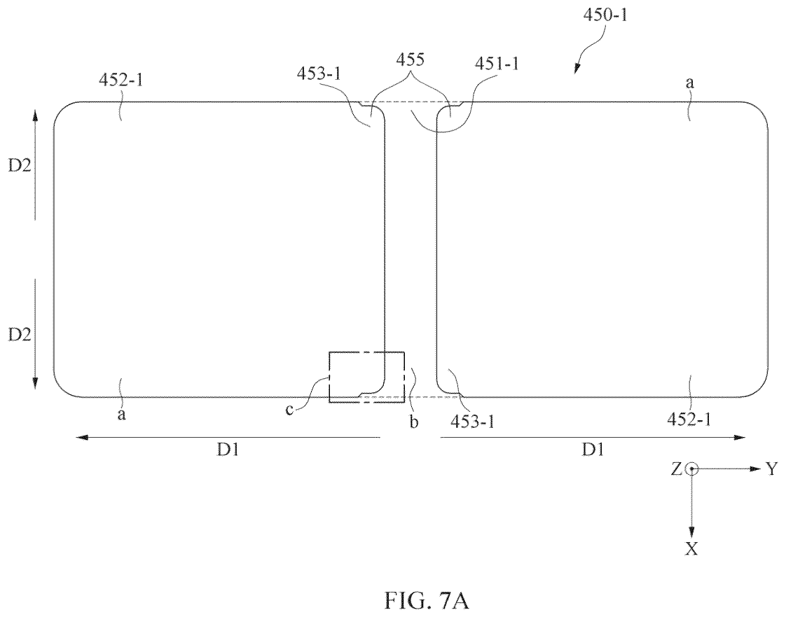

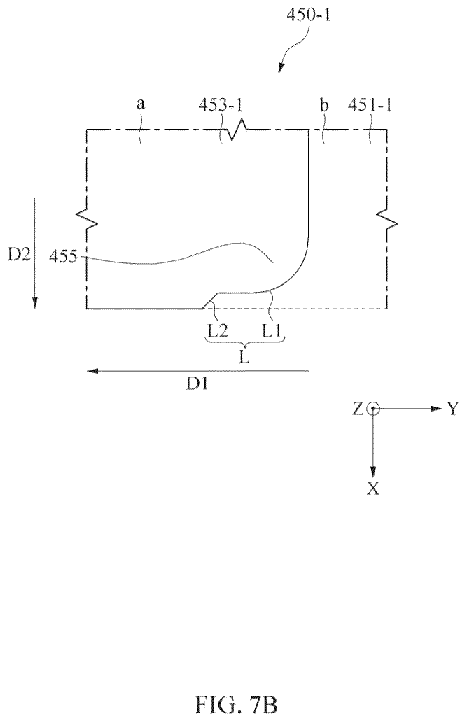

FIG. 7A is a plan view of an adhesive layer 450-1 according to one or more embodiments, and FIG. 7B is an enlarged view of the adhesive layer 450-1 according to one or more embodiments. Specifically, FIG. 7B is an enlarged view of Area c of FIG. 7A.

Referring to FIG. 7A and FIG. 7B, an adhesive layer 450-1 (e.g., the adhesive layer 450 of FIG. 5A, FIG. 5B, or FIG. 6) according to one or more embodiments may include an edge area 455.

Hereinafter, the description provided above will not be repeated, and some configurations and structures of the adhesive layer 450-1 may be replaced, added, or omitted within a range that those skilled in the art can easily understand by referring to the following drawings and description. Additionally, the features, or at least one configuration in the embodiments described above may be combined with the adhesive layer 450-1 unless technically obviously infeasible.

In one or more embodiments, the adhesive layer 450-1 may include an adhesive area a and a non-adhesive area b. The adhesive area a may be an area that bonds neighboring components. The non-adhesive area b may be an area that does not bond neighboring components. In another example, the non-adhesive area b may be a weak-adhesion area a that has a weaker adhesive strength than the adhesive area a.

In one or more embodiments, the adhesive layer 450-1 may bond neighboring components through the adhesive area a. Additionally, the adhesive layer 450-1 may reduce the movement constraints of neighboring components through the non-adhesive area b.

In one or more embodiments, the adhesive layer 450-1 may include a folding portion 451-1 (e.g., the folding portion 451 of FIG. 5B or FIG. 6), a first portion 452-1 (e.g., the first portion 452 of FIG. 5B or FIG. 6), and a second portion 453-1 (e.g., the second portion 453 of FIG. 5B or FIG. 6).

Hereinafter, in describing the adhesive layer 450-1 including the folding portion 451-1, the first portion 452-1, and the second portion 453-1, the description provided above will not be repeated, and the above descriptions may apply substantially identically or similarly to the adhesive layer 450-1 of FIG. 7A and FIG. 7B.

In one or more embodiments, the second portion 453-1 may include the edge area 455. The edge area 455 may be an end portion of at least one side (e.g., the +X direction or the −X direction) of the second portion 453-1 in the second direction D2.

In one or more embodiments, the edge area 455 may be formed in a shape in which the width of the non-adhesive area b (e.g., the width in the second direction D2) gradually decreases in the first direction D1. By the edge area 455, the second portion 453-1 may have a ratio of the adhesive area a per unit area increasing in the first direction D1.

For example, the end portion of the second portion 453-1 in the second direction D2 may include a non-adhesive area b. The width of the non-adhesive area b may gradually decrease in the first direction D1.

In one or more embodiments of the present disclosure, the second portion 453-1 including the edge area 455 may disperse the stress concentrated at the connection site of the adhesive area a and the non-adhesive area b to a wide range, and may alleviate the stress applied to a display panel (e.g., the display panel 410 of FIG. 5A).

In one or more embodiments, the edge area 455 may include a boundary line L. The boundary line L may be an area where the adhesive area a and the non-adhesive area b face each other. The boundary line L may be an area where stress transmitted from one adhesive component (e.g., the support plate 430) to another component (e.g., the display panel 410) is concentrated by the adhesive area a.

In one or more embodiments, the boundary line L may have a shape curved in the first direction D1. For example, the boundary line L may include at least one of a first line shape L1 and a second line shape L2.

In one or more embodiments, the first line shape L1 may be a line curved into a rounded or curved shape in the first direction D1. In one or more embodiments, the second line shape L2 may be a line curved in a diagonal shape in the first direction D1.

In one or more embodiments of the present disclosure, the boundary line L may gradually increase the ratio of the adhesive area a in the first direction D1. Through the curved shape, the second portion 453-1 may effectively disperse the stress concentrated at the boundary line L of the edge area 455.

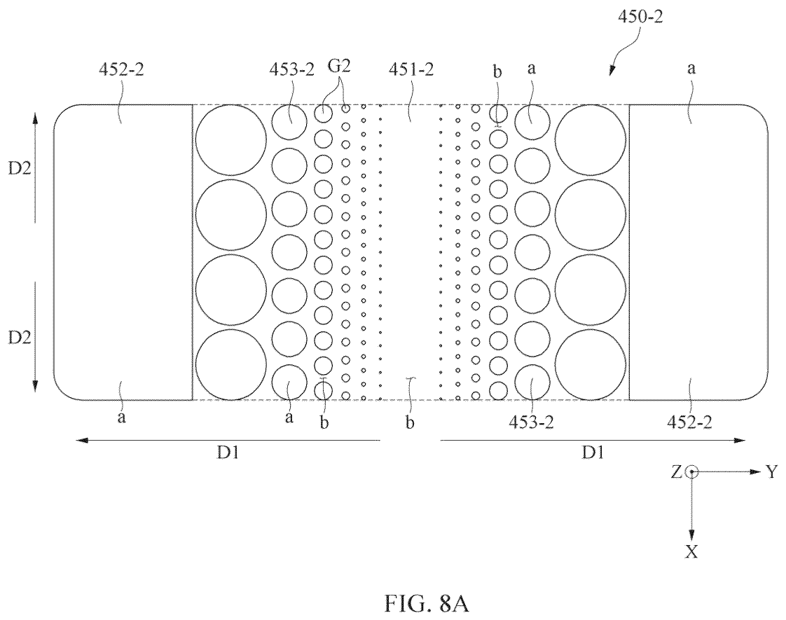

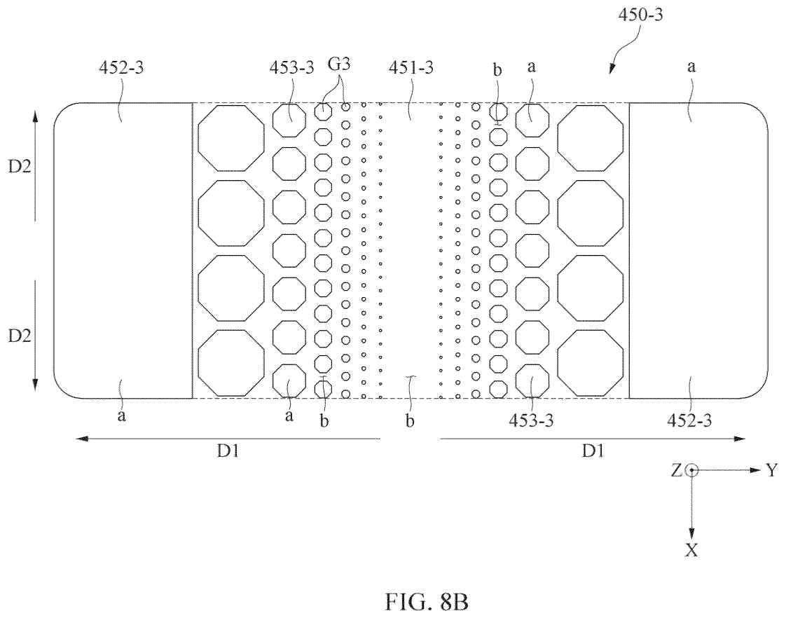

FIG. 8A is a plan view of an adhesive layer 450-2 according to one or more embodiments.

Referring to FIG. 8A, an adhesive layer 450-2 according to one or more embodiments may include a pattern shape in which geometric structures G2 having circular or oval shapes are arranged.

Hereinafter, the description provided above will not be repeated, and some configurations and structures of the adhesive layer 450-2 may be replaced, added, or omitted within a range that those skilled in the art can easily understand by referring to the following drawings and description. Additionally, the features, or at least one configuration in the embodiments described above may be combined with the adhesive layer 450-2 unless technically obviously infeasible.

In one or more embodiments, the adhesive layer 450-2 may include an adhesive area a and a non-adhesive area b. The adhesive area a may be an area that bonds neighboring components. The non-adhesive area b may be an area that does not bond neighboring components. In another example, the non-adhesive area b may be a weak-adhesion area a that has a weaker adhesive strength than the adhesive area a.

In one or more embodiments, the adhesive layer 450-2 may bond neighboring components through the adhesive area a. Additionally, the adhesive layer 450-2 may reduce the movement constraints of neighboring components through the non-adhesive area b.

In one or more embodiments, the adhesive layer 450-2 may include a folding portion 451-2 (e.g., the folding portion 451 of FIG. 5B or FIG. 6), a first portion 452-2 (e.g., the first portion 452 of FIG. 5B or FIG. 6), and a second portion 453-2 (e.g., the second portion 453 of FIG. 5B or FIG. 6).

Hereinafter, in describing the adhesive layer 450-2 including the folding portion 451-2, the first portion 452-2, and the second portion 453-2, the description provided above will not be repeated, and the above descriptions may apply substantially identically or similarly to the adhesive layer 450-2 of FIG. 8A.

In one or more embodiments, the adhesive area a of the second portion 453-2 may be formed in a pattern shape in which a plurality of geometric structures G2 are arranged. The non-adhesive area b of the second portion 453-2 may be formed in a shape surrounding each of the plurality of geometric structures G2.

For example, as shown in FIG. 8A, each of the plurality of geometric structures G2 may be formed in a circular or oval shape. The plurality of geometric structures G2 in circular or oval shapes may prevent stress from being concentrated at corners, unlike polygonal structures.

In one or more embodiments, the plurality of geometric structures G2 may be arranged to be spaced apart from each other, and the non-adhesive area b may be formed as a spaced area between the plurality of geometric structures G2. However, embodiments are not limited thereto, and at least some of the plurality of geometric structures G2 may be partially connected or continuous.

In one or more embodiments, the pattern shape of the adhesive area a of the second portion 453-2 may be a shape in which a plurality of geometric structures G2 of different sizes and shapes are arranged in the first direction D1. For example, the second portion 453-2 may have a pattern shape in which the area of each of the plurality of geometric structures G2 increases in the first direction D1.

In one or more embodiments of the present disclosure, the adhesive layer 450-2 may have, through the pattern shape of the second portion 453-2, a ratio of the non-adhesive area b per unit area decreasing in the first direction D1 and a ratio of the adhesive area a increasing in the first direction D1.

In one or more embodiments, the pattern shape of the second portion 453-2 may be a shape in which a plurality of geometric structures G2 of substantially the same size and shape are arranged in the second direction D2.

In one or more embodiments, the pattern shape of the adhesive area a of the second portion 453-2 may have an interval between the plurality of geometric structures G2 gradually decreasing in the first direction D1. As the plurality of geometric structures G2 are arranged to be gradually closer in the first direction D1, the ratio of the non-adhesive area b per unit area may decrease in the first direction D1, and the ratio of the adhesive area a may increase in the first direction D1.

FIG. 8B is a plan view of an adhesive layer 450-3 according to one or more embodiments.

Referring to FIG. 8B, an adhesive layer 450-3 according to one or more embodiments may include a pattern shape in which geometric structures G3 formed in polygonal shapes such as octagonal shapes are arranged.

Hereinafter, the description provided above will not be repeated, and some configurations and structures of the adhesive layer 450-3 may be replaced, added, or omitted within a range that those skilled in the art can easily understand by referring to the following drawings and description. Additionally, the features, or at least one configuration in the embodiments described above may be combined with the adhesive layer 450-3 unless technically obviously infeasible.

In one or more embodiments, the adhesive layer 450-3 may include an adhesive area a and a non-adhesive area b. The adhesive area a may be an area that bonds neighboring components. The non-adhesive area b may be an area that does not bond neighboring components. In another example, the non-adhesive area b may be a weak-adhesion area a that has a weaker adhesive strength than the adhesive area a.

In one or more embodiments, the adhesive layer 450-3 may bond neighboring components through the adhesive area a. Additionally, the adhesive layer 450-3 may reduce the movement constraints of neighboring components through the non-adhesive area b.

In one or more embodiments, the adhesive layer 450-3 may include a folding portion 451-3 (e.g., the folding portion 451 of FIG. 5B or FIG. 6), a first portion 452-3 (e.g., the first portion 452 of FIG. 5B or FIG. 6), and a second portion 453-3 (e.g., the second portion 453 of FIG. 5B or FIG. 6).

Hereinafter, in describing the adhesive layer 450-3 including the folding portion 451-3, the first portion 452-3, and the second portion 453-3, the description provided above will not be repeated, and the above descriptions may apply substantially identically or similarly to the adhesive layer 450-3 of FIG. 8B.

In one or more embodiments, the adhesive area a of the second portion 453-3 may be formed in a pattern shape in which a plurality of geometric structures G3 are arranged. The non-adhesive area b of the second portion 453-3 may be formed in a shape surrounding each of the plurality of geometric structures G3.

For example, as shown in FIG. 8B, each of the plurality of geometric structures G3 may be formed in a polygonal shape such as an octagonal shape. The plurality of geometric structures G3 in polygonal shapes may evenly disperse the stress in the adhesive area a, and may also be advantageous in implementing uniformly repeated shapes.

In one or more embodiments, the plurality of geometric structures G3 may be arranged to be spaced apart from each other, and the non-adhesive area b may be formed as a spaced area between the plurality of geometric structures G3. However, embodiments are not limited thereto, and at least some of the plurality of geometric structures G3 may be partially connected or continuous.

In one or more embodiments, the pattern shape of the adhesive area a of the second portion 453-3 may be a shape in which a plurality of geometric structures G3 of different sizes and shapes are arranged in the first direction D1. For example, the second portion 453-3 may have a pattern shape in which the area of each of the plurality of geometric structures G3 increases in the first direction D1.

In one or more embodiments of the present disclosure, the adhesive layer 450-3 may have, through the pattern shape of the second portion 453-3, a ratio of the non-adhesive area b per unit area decreasing in the first direction D1 and a ratio of the adhesive area a increasing in the first direction D1.

In one or more embodiments, the pattern shape of the second portion 453-3 may be a shape in which a plurality of geometric structures G3 of substantially the same size and shape are arranged in the second direction D2.

In one or more embodiments, the pattern shape of the adhesive area a of the second portion 453-3 may have an interval between the plurality of geometric structures G3 gradually decreasing in the first direction D1. As the plurality of geometric structures G3 are arranged to be gradually closer in the first direction D1, the ratio of the non-adhesive area b per unit area may decrease in the first direction D1, and the ratio of the adhesive area a may increase in the first direction D1.

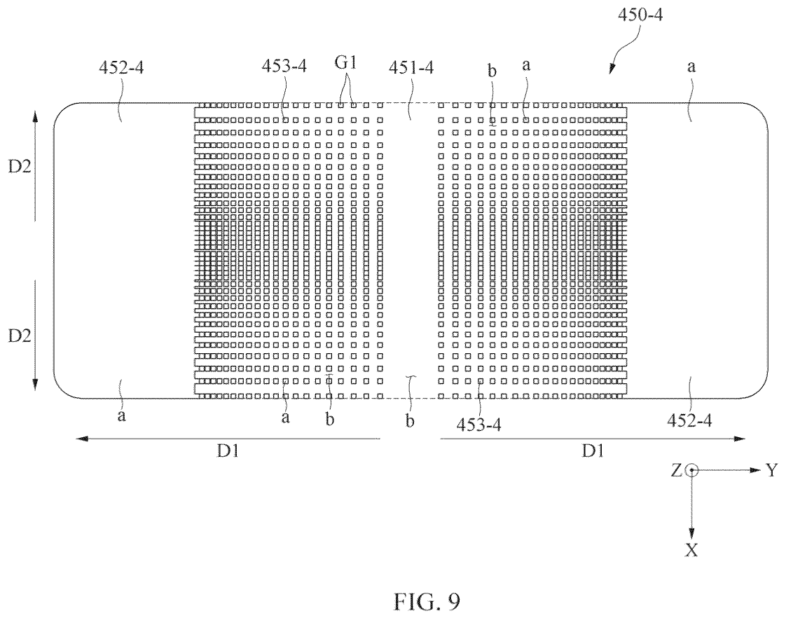

FIG. 9 is a plan view of an adhesive layer 450-4 according to one or more embodiments.

Referring to FIG. 9, a plurality of geometric structures G1 of an adhesive layer 450-4 according to one or more embodiments may have an interval varying in the second direction D2.

Hereinafter, the description provided above will not be repeated, and some configurations and structures of the adhesive layer 450-4 may be replaced, added, or omitted within a range that those skilled in the art can easily understand by referring to the following drawings and description. Additionally, the features, or at least one configuration in the embodiments described above may be combined with the adhesive layer 450-4 unless technically obviously infeasible.

In one or more embodiments, the adhesive layer 450-4 may include an adhesive area a and a non-adhesive area b. The adhesive area a may be an area that bonds neighboring components. The non-adhesive area b may be an area that does not bond neighboring components. In another example, the non-adhesive area b may be a weak-adhesion area a that has a weaker adhesive strength than the adhesive area a.

In one or more embodiments, the adhesive layer 450-4 may bond neighboring components through the adhesive area a. Additionally, the adhesive layer 450-4 may reduce the movement constraints of neighboring components through the non-adhesive area b.

In one or more embodiments, the adhesive layer 450-4 may include a folding portion 451-4 (e.g., the folding portion 451 of FIG. 5B or FIG. 6), a first portion 452-4 (e.g., the first portion 452 of FIG. 5B or FIG. 6), and a second portion 453-4 (e.g., the second portion 453 of FIG. 5B or FIG. 6).

Hereinafter, in describing the adhesive layer 450-4 including the folding portion 451-4, the first portion 452-4, and the second portion 453-4, the description provided above will not be repeated, and the above descriptions may apply substantially identically or similarly to the adhesive layer 450-4 of FIG. 9.

In one or more embodiments, the adhesive area a of the second portion 453-4 may be formed in a pattern shape in which a plurality of geometric structures G1 are arranged. The non-adhesive area b of the second portion 453-4 may be formed in a shape surrounding each of the plurality of geometric structures G1.

For example, each of the plurality of geometric structures G1 may have a quadrangular shape. However, embodiments are not limited thereto, and each of the plurality of geometric structures G1 may have a circular, oval, or polygonal shape.

In one or more embodiments, the adhesive area a of the second portion 453-4 may be formed in a pattern shape in which a plurality of geometric structures G1 are arranged to be spaced apart from each other. The non-adhesive area b of the second portion 453-4 may be formed as a spaced area between the plurality of geometric structures G1.

In one or more embodiments, in the second portion 453-4, from the end portions in the second direction D2 toward the center of the second portion 453-4, the interval between the plurality of geometric structures G1 may decrease.

In one or more embodiments, as the plurality of geometric structures G1 are arranged to be gradually farther in the second direction D2, the ratio of the non-adhesive area b per unit area may decrease in the second direction D2, and the ratio of the adhesive area a may increase in the second direction D2.

In one or more embodiments of the present disclosure, by changing the ratio of the adhesive area a in the second direction D2, the second portion 453-4 may effectively disperse the stress concentrated at the end portions in the second direction D2.

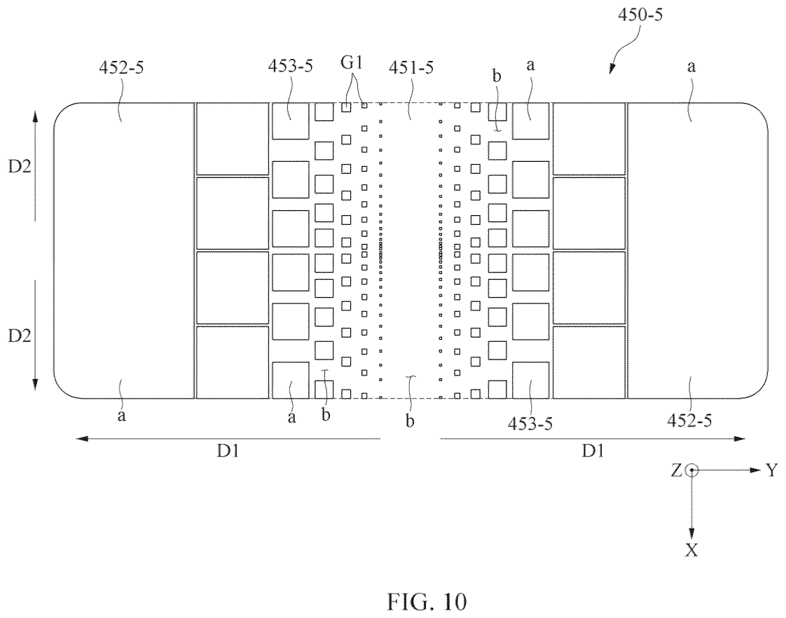

FIG. 10 is a plan view of an adhesive layer 450-5 according to one or more embodiments.

Referring to FIG. 10, an adhesive layer 450-5 according to one or more embodiments may change the ratio of an adhesive area a of a second portion 453-5 using a plurality of methods.

Hereinafter, the description provided above will not be repeated, and some configurations and structures of the adhesive layer 450-5 may be replaced, added, or omitted within a range that those skilled in the art can easily understand by referring to the following drawings and description. Additionally, the features, or at least one configuration in the embodiments described above may be combined with the adhesive layer 450-5 unless technically obviously infeasible.

In one or more embodiments, the adhesive layer 450-5 may include an adhesive area a and a non-adhesive area b. The adhesive area a may be an area that bonds neighboring components. The non-adhesive area b may be an area that does not bond neighboring components. In another example, the non-adhesive area b may be a weak-adhesion area a that has a weaker adhesive strength than the adhesive area a.

In one or more embodiments, the adhesive layer 450-5 may bond neighboring components through the adhesive area a. Additionally, the adhesive layer 450-5 may reduce the movement constraints of neighboring components through the non-adhesive area b.

In one or more embodiments, the adhesive layer 450-5 may include a folding portion 451-5 (e.g., the folding portion 451 of FIG. 5B or FIG. 6), a first portion 452-5 (e.g., the first portion 452 of FIG. 5B or FIG. 6), and a second portion 453-5 (e.g., the second portion 453 of FIG. 5B or FIG. 6).

Hereinafter, in describing the adhesive layer 450-5 including the folding portion 451-5, the first portion 452-5, and the second portion 453-5, the description provided above will not be repeated, and the above descriptions may apply substantially identically or similarly to the adhesive layer 450-5 of FIG. 10.

In one or more embodiments, the adhesive area a of the second portion 453-5 may be formed in a pattern shape in which a plurality of geometric structures G1 are arranged. The non-adhesive area b of the second portion 453-5 may be formed in a shape surrounding each of the plurality of geometric structures G1.

For example, each of the plurality of geometric structures G1 may have a quadrangular shape. However, embodiments are not limited thereto, and each of the plurality of geometric structures G1 may have a circular, oval, or polygonal shape.

In one or more embodiments, the adhesive area a of the second portion 453-5 may be formed in a pattern shape in which a plurality of geometric structures G1 are arranged to be spaced apart from each other. The non-adhesive area b of the second portion 453-5 may be formed as a spaced area between the plurality of geometric structures G1.

In one or more embodiments, the pattern shape of the adhesive area a of the second portion 453-5 may be a shape in which a plurality of geometric structures G1 of different sizes and shapes are arranged in the first direction D1. For example, the second portion 453-5 may have a pattern shape in which the area of each of the plurality of geometric structures G1 increases in the first direction D1.

In one or more embodiments, the pattern shape of the adhesive area a of the second portion 453-5 may be a shape in which a plurality of geometric structures G1 of substantially the same size and shape are arranged in a second direction D2 perpendicular to the first direction D1.

In one or more embodiments of the present disclosure, the adhesive layer 450-5 may have, through the pattern shape of the second portion 453-5, a ratio of the non-adhesive area b per unit area decreasing in the first direction D1 and a ratio of the adhesive area a increasing in the first direction D1.

In one or more embodiments, the pattern shape of the adhesive area a of the second portion 453-5 may have an interval between the plurality of geometric structures G1 gradually decreasing in the first direction D1. As the plurality of geometric structures G1 are arranged to be gradually closer in the first direction D1, the ratio of the non-adhesive area b per unit area may decrease in the first direction D1, and the ratio of the adhesive area a may increase in the first direction D1.

In one or more embodiments, in the second portion 453-5, from the end portions in the second direction D2 toward the center of the second portion 453-5, the interval between the plurality of geometric structures G1 may decrease.

In one or more embodiments, as the plurality of geometric structures G1 are arranged to be gradually farther in the second direction D2, the ratio of the non-adhesive area b per unit area may decrease in the second direction D2, and the ratio of the adhesive area a may increase in the second direction D2.

In one or more embodiments of the present disclosure, the adhesive layer 450-5 may effectively disperse the stress concentrated at a predetermined area in the second portion 453-5, through a pattern shape in which the area of each of the plurality of geometric structures G1 increases in the first direction D1, the interval between the plurality of geometric structures G1 decreases in the first direction D1, and/or the interval between the plurality of geometric structures G1 increases in the second direction D2.

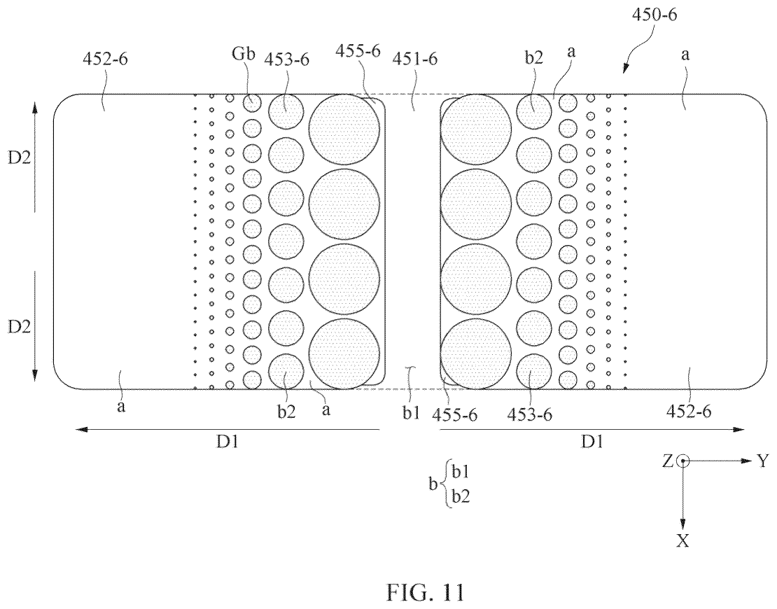

FIG. 11 is a plan view of an adhesive layer 450-6 according to one or more embodiments.

Referring to FIG. 11, a non-adhesive area b of a second portion 453-6 according to one or more embodiments may include a first non-adhesive portion b1 and a second non-adhesive portion b2.

Hereinafter, the description provided above will not be repeated, and some configurations and structures of the adhesive layer 450-6 may be replaced, added, or omitted within a range that those skilled in the art can easily understand by referring to the following drawings and description. Additionally, the features, or at least one configuration in the embodiments described above may be combined with the adhesive layer 450-6 unless technically obviously infeasible.

In one or more embodiments, the adhesive layer 450-6 may include an adhesive area a and a non-adhesive area b. The adhesive area a may be an area that bonds neighboring components. The non-adhesive area b may be an area that does not bond neighboring components. In another example, the non-adhesive area b may be a weak-adhesion area a that has a weaker adhesive strength than the adhesive area a.

In one or more embodiments, the adhesive layer 450-6 may bond neighboring components through the adhesive area a. Additionally, the adhesive layer 450-6 may reduce the movement constraints of neighboring components through the non-adhesive area b.

In one or more embodiments, the adhesive layer 450-6 may include a folding portion 451-6 (e.g., the folding portion 451 of FIG. 5B or FIG. 6), a first portion 452-6 (e.g., the first portion 452 of FIG. 5B or FIG. 6), and a second portion 453-6 (e.g., the second portion 453 of FIG. 5B or FIG. 6).

Hereinafter, in describing the adhesive layer 450-6 including the folding portion 451-6, the first portion 452-6, and the second portion 453-6, the description provided above will not be repeated, and the above descriptions may apply substantially identically or similarly to the adhesive layer 450-6 of FIG. 11.

In one or more embodiments, the non-adhesive area b of the second portion 453-6 may include a first non-adhesive portion b1 and a second non-adhesive portion b2. The first non-adhesive portion b1 may be an area including an open space. The second non-adhesive portion b2 may be an area including a non-adhesive material.

However, this is merely an example, and the first non-adhesive portion b1 of one or more embodiments may be an area including a non-adhesive material, and the second non-adhesive portion b2 may be an area including an open space. In another example, the first non-adhesive portion b1 and the second non-adhesive portion b2 of one or more embodiments may be areas including open spaces. In another example, the first non-adhesive portion b1 and the second non-adhesive portion b2 of one or more embodiments may be areas including a non-adhesive material.

In one or more embodiments, the first non-adhesive portion b1 of the second portion 453-6 may be a partial area extending from the non-adhesive portion b of the folding portion 451-6. The first non-adhesive portion b1 may be provided at both end portions of the second portion 453-6 in the second direction D2.

For example, the second portion 453-6 may include an edge area 455-6. The edge area 455-6 may be an end portion of at least one side (e.g., the +X direction or the −X direction) of the second portion 453-6 in the second direction D2.

In one or more embodiments, the edge area 455-6 may be formed in a shape in which the width of the first non-adhesive area b1 (e.g., the width in the second direction D2) gradually decreases in the first direction D1. By the edge area 455-6, the second portion 453-6 may have a ratio of the adhesive area a per unit area increasing in the first direction D1.

For example, the end portion of the second portion 453-6 in the second direction D2 may include a second non-adhesive area b2. The width of the first non-adhesive area b1 may gradually decrease in the first direction D1.

In one or more embodiments of the present disclosure, the second portion 453-6 including the edge area 455-6 may disperse the stress concentrated at the connection site of the adhesive area a and the non-adhesive area b to a wide range, and may alleviate the stress applied to a display panel (e.g., the display panel 410 of FIG. 5A).

In one or more embodiments, the second non-adhesive area b2 may be formed in a pattern shape in which a plurality of geometric structures Gb are arranged. The adhesive area a may be formed in a shape surrounding each of the plurality of geometric structures Gb.

For example, each of the plurality of geometric structures Gb may have a circular shape. However, embodiments are not limited thereto, and each of the plurality of geometric structures Gb may have an oval or polygonal shape.

In one or more embodiments, the pattern shape of the second non-adhesive area b2 of the second portion 453-6 may have an interval between the plurality of geometric structures Gb gradually increasing in the first direction D1. As the plurality of geometric structures Gb are arranged to be gradually farther in the first direction D1, the ratio of the non-adhesive area b per unit area may decrease in the first direction D1, and the ratio of the adhesive area a may increase in the first direction D1.

In one or more embodiments, the pattern shape of the second non-adhesive area b2 of the second portion 453-6 may be a shape in which a plurality of geometric structures Gb of different sizes and shapes are arranged in the first direction D1. For example, the second portion 453-6 may have a pattern shape in which the area of each of the plurality of geometric structures Gb decreases in the first direction D1. As the area of each of the plurality of geometric structures Gb decreases, the ratio of the non-adhesive area b per unit area may decrease in the first direction D1, and the ratio of the adhesive area a may increase in the first direction D1.

In one or more embodiments, the pattern shape of the second non-adhesive area b2 of the second portion 453-6 may be a shape in which a plurality of geometric structures Gb of substantially the same size and shape are arranged in a second direction D2 perpendicular to the first direction D1.

In one or more embodiments of the present disclosure, the adhesive layer 450-6 may have, through the pattern shape of the second non-adhesive area b2 of the second portion 453-6, a ratio of the non-adhesive area b per unit area decreasing in the first direction D1 and a ratio of the adhesive area a increasing in the first direction D1.

In one or more embodiments of the present disclosure, the adhesive layer 450-6 may effectively disperse the stress concentrated at a predetermined area in the second portion 453-6, through a pattern shape in which the area of each of the plurality of geometric structures Gb decreases in the first direction D1 or the interval between the plurality of geometric structures Gb increases in the first direction D1.

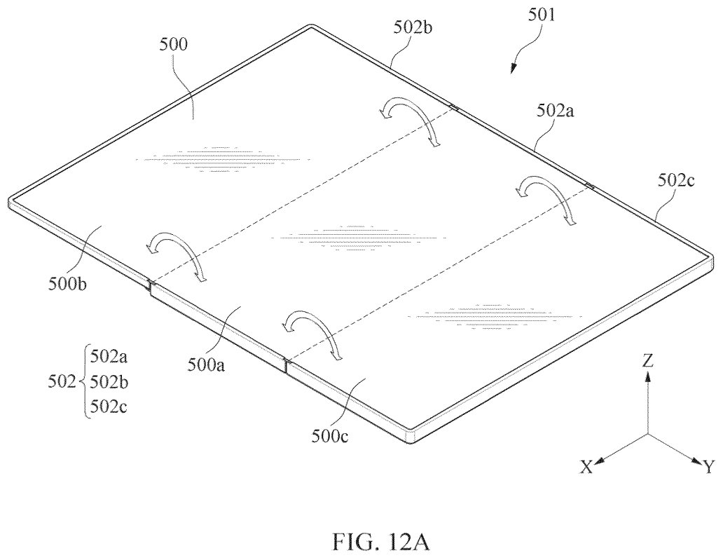

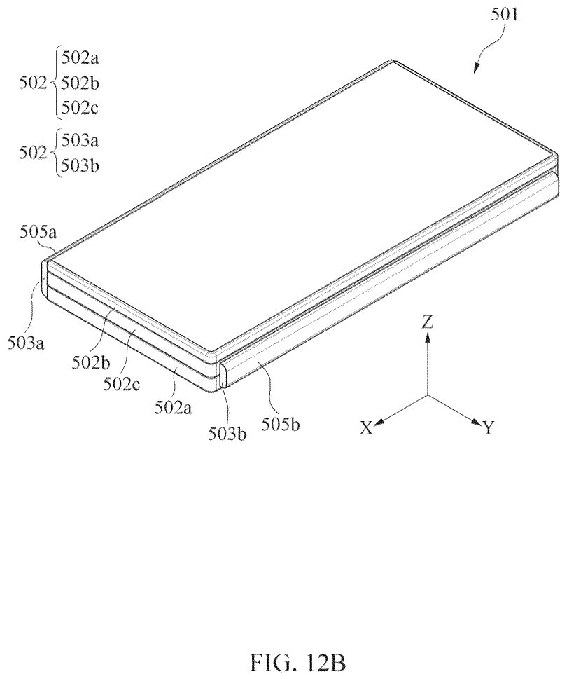

FIG. 12A is a view illustrating an unfolded state of an electronic device 501 according to one or more embodiments, and FIG. 12B is a view of a folded state of the electronic device 501 according to one or more embodiments.

Referring to FIG. 12A and FIG. 12B, an electronic device 501 (e.g., the electronic device 101 of FIG. 1, the electronic device 201 of FIG. 2A and FIG. 2B, the electronic device 301 of FIG. 3A and FIG. 3B, or the electronic device 401 of FIG. 4) according to one or more embodiments may include at least a portion of a display module 500 (e.g., the display module 160 of FIG. 1, the display 261 of FIG. 2A and FIG. 2B, the display 350 of FIG. 3A and FIG. 3B, or the display module 400 of FIG. 4 or FIG. 5A) and a housing structure 502 (e.g., the housing structure 210 and housing structure 220 of FIG. 2A and FIG. 2B, the housing structure 310 and housing structure 320 of FIG. 3A and FIG. 3B, or the housing structure 403 of FIG. 4).

Hereinafter, the description provided above will not be repeated, and some configurations and structures of the electronic device 501 may be replaced, added, or omitted within a range that those skilled in the art can easily understand by referring to the following drawings and description. Additionally, the features, or at least one configuration in the embodiments described above may be combined with the electronic device 501 unless technically obviously infeasible.

In one or more embodiments, the electronic device 501 may be a bendable (or foldable) device. For example, the electronic device 501 may be a multi-foldable device that is bendable at least twice.

In one or more embodiments, the electronic device 501 may include a housing structure 502 and a display module 500.

In one or more embodiments, the housing structure 502 may form the exterior of the electronic device 501. The housing structure 502 may include a first housing portion 502a, a second housing portion 502b, and a third housing portion 502c.

In one or more embodiments, the first housing portion 502a and the second housing portion 502b may be connected in a foldable manner. For example, the second housing portion 502b may be rotatably connected to an end portion on one side (e.g., the −Y direction) of the first housing portion 502a.

In one or more embodiments, the first housing portion 502a and the third housing portion 502c may be connected in a foldable manner. For example, the third housing portion 502c may be rotatably connected to an end portion on the other side (e.g., the +Y direction) of the first housing portion 502a.

In one or more embodiments, a plurality of hinge assemblies 503 may include a first hinge assembly 503a and a second hinge assembly 503b. The first hinge assembly 503a and the second hinge assembly 503b may be disposed on both sides of the first housing portion 502a. In one or more embodiments, the first hinge assembly 503a and the second hinge assembly 503b may operate independently of each other.

In one or more embodiments, the first hinge assembly 503a may connect the first housing portion 502a and the second housing portion 502b. The second hinge assembly 503b may connect the first housing portion 502a and the third housing portion 502c.

In one or more embodiments, by means of the first hinge assembly 503a, one of the first housing portion 502a and the second housing portion 502b may rotate relative to the other about the first hinge assembly 503a.

In one or more embodiments, by means of the second hinge assembly 503b, one of the first housing portion 502a and the third housing portion 502c may rotate relative to the other about the second hinge assembly 503b.

In one or more embodiments, a first hinge cover 505a may cover the first hinge assembly 503a. A second hinge cover 505b may cover the second hinge assembly 503b. Each of the first hinge cover 505a and the second hinge cover 505b may be disposed in the housing structure 502 or exposed to the outside of the housing structure 502 based on the operating states of the first hinge assembly 503a and the second hinge assembly 503b.

In one or more embodiments, the electronic device 501 may have a folded state that varies in response to the rotation of at least a portion of the first housing portion 502a, the second housing portion 502b, and the third housing portion 502c.

For example, the electronic device 501 may have a varying state between a fully folded state, a partially folded state (or a partially unfolded state), and a fully unfolded state, depending on the unfolded state of the components of the housing structure 502.

In one or more embodiments, the display module 500 may include a flexible display panel disposed in a space formed by a plurality of housing structures 502. According to one or more embodiments, based on the unfolded state (e.g., the state of FIG. 12B), a surface on which the display module 500 is disposed (or a surface on which the display module 500 is visually viewed from the outside of the electronic device 501) may be defined as a front surface of the electronic device 501. In addition, a surface opposite to the front surface may be defined as a rear surface of the electronic device 501. Further, a surface surrounding a space between the front surface and the rear surface may be defined as a side surface of the electronic device 501.

In one or more embodiments, the display module 500 may include a first area 500a, a second area 500b, and a third area 500c. The first area 500a may be disposed in the first housing portion 502a, the second area 500b may be disposed in the second housing portion 502b, and the third area 500c may be disposed in the third housing portion 502c.

In one or more embodiments, in a state in which the electronic device 501 is fully folded state, the first housing portion 502a, the second housing portion 502b, and the third housing portion 502c may be stacked in one direction (e.g., the Z-axis direction).

For example, the third housing portion 502c may be disposed on the top of the first housing portion 502a, and the second housing portion 502b may be disposed on the top of the third housing portion 502c.

In one or more embodiments, as the first housing portion 502a and the second housing portion 502b are unfolded, the electronic device 501 may be in a partially folded state (or a partially unfolded state). When the first housing portion 502a and the second housing portion 502b are unfolded and then, the first housing portion 502a and the third housing portion 502c are unfolded, the electronic device 501 may be in a fully unfolded state.

In one or more embodiments of the present disclosure, a user may adjust the unfolded state of the electronic device according to the usage environment or the user's preference, and the electronic device 501 may provide an improved usage experience to the user.

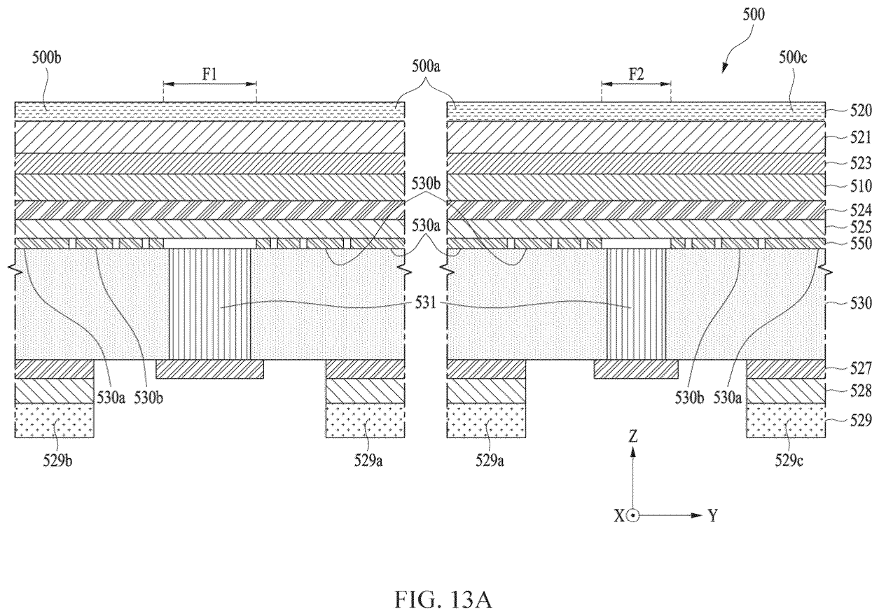

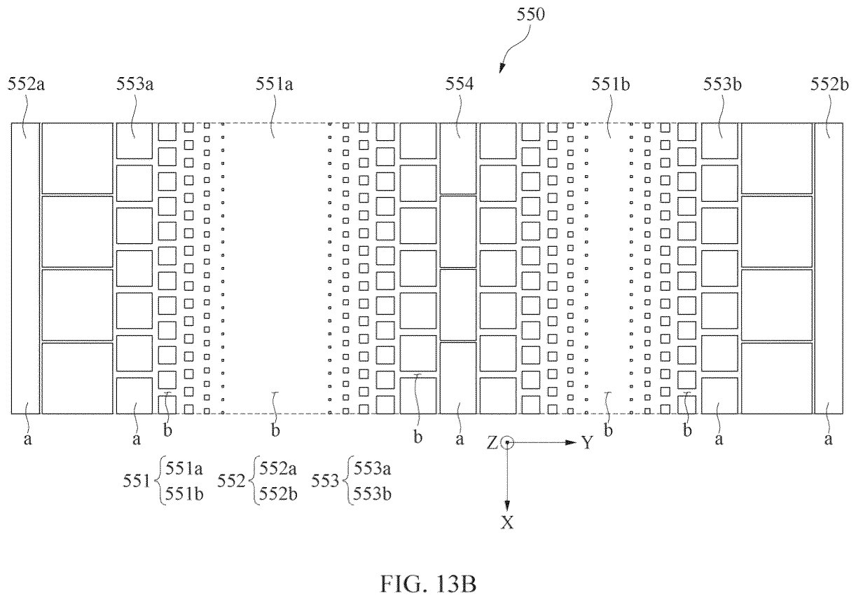

FIG. 13A is a schematic diagram of a cross section of a display module 500 according to one or more embodiments, and FIG. 13B is a plan view of an adhesive layer 550 according to one or more embodiments.

Referring to FIG. 13A and FIG. 13B, a display module 500 according to one or more embodiments may include at least a portion of a display panel 510, a foldable glass 520, a polarizer 523 (e.g., a polarizing film), a polymer layer 525, a shield layer 527, a reinforcement plate 529, and a support plate 530.

Hereinafter, the description provided above will not be repeated, and some configurations and structures of the display module 500 may be replaced, added, or omitted within a range that those skilled in the art can easily understand by referring to the following drawings and description. Additionally, the features, or at least one configuration in the embodiments described above may be combined with the display module 500 unless technically obviously infeasible.

In one or more embodiments, the display module 500 may include two folding areas, first folding area F1 and second folding area F2, (e.g., the folding area 261c of FIG. 2A, the folding area 353 of FIG. 3A, or the folding area F of FIG. 5A). The display module 500 may be bent so that the areas on both sides (e.g., the +Y side and the −Y side) may face each other based on the folding area 353.

In one or more embodiments, the display module 500 may implement a display of a foldable type that is bendable, a rollable type with a variable display area, a slidable type, or an extensible type.

In one or more embodiments, the two folding areas, first filing area F1 and second folding area F2, may include a first folding area F1 and a second folding area F2. The first folding area F1 may be provided between the first area 500a and the second area 500b. The second folding area F2 may be provided between the first area 500a and the third area 500c.

In one or more embodiments, the foldable glass 520 may support and protect the display module 500. For example, the foldable glass 520 may include a plurality of bridges disposed in an area corresponding to a folding area 511 of the display module 500. The plurality of bridges may provide improved flexibility to the display module 500, assist in the bending motion of the foldable glass 520, and reinforce the rigidity of the display module 500.

In one or more embodiments, the polarizer 523 may selectively transmit light that is generated from a light source of the display panel 510 and vibrates in a predetermined direction. According to one or more embodiments, the polarizer 523 may be formed integrally with the display panel 510.

In one or more embodiments, the display panel 510 may include a plurality of pixels and a wiring structure (e.g., an electrode pattern). The display panel 510 may be a foldable display panel. The display panel 510 may be supported by at least one layer (e.g., the support plate 530 and the reinforcement plate 529).

In one or more embodiments, the polymer layer 525 may be disposed under the display panel 510 (e.g., in the −Z direction). The polymer layer 525 may provide a dark background to ensure the visibility of the display panel 510. In another example, the polymer layer 525 may be formed of a buffering material to cushion the shock transmitted to the display module 500.

In one or more embodiments, to waterproof the display module 500, the polymer layer 525 may be omitted, or the polymer layer 525 may be disposed under the support plate 530. In one or more embodiments, the support plate 530 may be formed in a shape providing flexibility to the display module 500.

In one or more embodiments, the support plate 530 may be a metal layer. For example, the support plate 530 may include at least one of steel use stainless (SUS) (e.g., stainless steel (STS)), Cu, Al, or metal CLAD (e.g., a stacked member in which SUS and Al are alternately disposed). In another example, the support plate 530 may include other alloy materials.

In one or more embodiments, the support plate 530 may help to reinforce the rigidity of the display module 500, shield ambient noise, or disperse heat emitted from heat dissipating components around.

In one or more embodiments, the support plate 530 may include a lattice pattern 531. The lattice pattern 531 may be provided at a position corresponding to the folding area F. In one or more embodiments, the lattice pattern 531 may include a plurality of lattice holes and a plurality of bridges between the plurality of lattice holes. The lattice pattern 531 may increase the flexibility and durability of the support plate 530.

In one or more embodiments, the support plate 530 may include a bendable region including at least one lattice pattern 531. For example, the bendable region of the support plate 530 may be an area corresponding to the lattice pattern 531, or may refer to the lattice pattern 531 and a partial area adjacent thereto.

In one or more embodiments, the support plate 530 may include at least one first region 530a and at least one second region 530b. The first region 530a may be a region spaced apart from the bendable region in a first direction D1. The second region 530b may be a region between the first region 530a and the bendable region.

The support plate 530 in one or more embodiments may help to smoothly perform the folding motion of the display module 500, and help to reinforce the rigidity of the display panel 510 and the display module 500.

In one or more embodiments, the display module 500 may further include at least one functional member disposed between the polymer layer 525 and the support plate 530, or under the support plate 530. For example, the functional member may include a graphite sheet for heat dissipation, a force-touch flexible printed circuit board (FPCB), a fingerprint sensor FPCB, an antenna radiator for communication, or a conductive/non-conductive tape.

In one or more embodiments, the shield layer 527 may include an elastic material (e.g., thermoplastic polyurethane (TPU)). The shield layer 527 may be disposed under the support plate 530. The shield layer 527 may cushion the shock transmitted to the support plate 530.

In one or more embodiments, the reinforcement plate 529 may include a first reinforcement area 529a facing a first housing portion (e.g., the first housing portion 502a of FIG. 12A and FIG. 12B), a second reinforcement area 529b facing a second housing portion (e.g., the second housing portion 502b of FIG. 12A and FIG. 12B), and a third reinforcement area 529c facing a third housing portion (e.g., the third housing portion 502c of FIG. 12A and FIG. 12B).

In one or more embodiments, the display module 500 may have some of the plurality of layers described above bonded together by at least some of adhesives, first adhesive 521, second adhesive 524, and third adhesive 528, and an adhesive layer 550.

In one or more embodiments, the adhesives, first adhesive 521, second adhesive 524, and third adhesive 528, and the adhesive layer 550 may include at least one of an optical clear adhesive (OCA), a pressure sensitive adhesive (PSA), a heat-reactive adhesive, a general adhesive, or a double-sided tape.

In one or more embodiments, the adhesives, first adhesive 521, second adhesive 524, and third adhesive 528, and the adhesive layer 550 may be formed of substantially the same material, or at least some thereof may be formed of different materials.

In one or more embodiments, the adhesives may include a first adhesive 521, a second adhesive 524, and a third adhesive 528. In one or more embodiments, the first adhesive 521 may bond the foldable glass 520 and the polarizer 523. In one or more embodiments, the second adhesive 524 may bond the display panel 510 and the polymer layer 525. In one or more embodiments, the third adhesive 528 may bond the shield layer 527 and the reinforcement plate 529.

In one or more embodiments, the adhesive layer 550 may be disposed between the display panel 510 and the support plate 530. For example, the adhesive layer 550 may bond the polymer layer 525 and the support plate 530.

In one or more embodiments, the adhesive layer 550 may include an adhesive area a and a non-adhesive area b. The adhesive area a may be an area that bonds neighboring components. The non-adhesive area b may be an area that does not bond neighboring components. In another example, the non-adhesive area b may be a weak-adhesion area a that has a weaker adhesive strength than the adhesive area a.

For example, the adhesive area a may bond the polymer layer 525 (or the display panel 510) and the support plate 530. For example, the non-adhesive area b may not be bonded to at least one of the polymer layer 525 (or the display panel 510) and the support plate 530.

In one or more embodiments, the adhesive layer 550 may bond neighboring components through the adhesive area a. Additionally, the adhesive layer 550 may reduce the movement constraints of neighboring components through the non-adhesive area b.

In one or more embodiments, the adhesive layer 550 may include a folding portion 551, a first portion 552, a second portion 553, and a third portion 554.

In one or more embodiments, the folding portion 551 may be an area that at least partially overlaps the folding area F in a direction facing the display module 500 or the display panel 510 (e.g., the −Z direction). In another example, the folding portion 551 may be an area facing the folding area F. In another example, the folding portion 551 may be an area corresponding to the lattice pattern 531.

In one or more embodiments, the adhesive area a of the adhesive layer 550 may be omitted from the bendable region of the support plate 530.

For example, in a state in which the electronic device 501 is unfolded, the folding portion 551 may be an area that overlaps at least partly with the folding area F when viewed in a direction perpendicular to the folding area F (e.g., the Z direction). The folding portion 551 may include the non-adhesive area b.

In one or more embodiments, the folding portion 551 may include a first sub-portion 551a and a second sub-portion 551b. The first sub-portion 551a may be an area overlapping the first folding area F1. The second sub-portion 551b may be an area overlapping the second folding area F2.

In one or more embodiments, the first portion 552 may be end portions of the adhesive layer 550 in both directions (e.g., the +Y direction or the −Y direction) perpendicular to the folding axis. In another example, the first portion 552 may be an area spaced apart from the folding portion 551 in a direction toward the end portions of the adhesive layer 550 in both directions perpendicular to the folding axis. In another example, the first portion 452 may be an area disposed on the first region 430a of the support plate 430.

In one or more embodiments, the first portion 552 may include a third sub-portion 552a and a fourth sub-portion 552b. The third sub-portion 552a may be one end portion that is closer to the first sub-portion 551a than the second sub-portion 551b. The fourth sub-portion 552b may be the other end portion that is closer to the second sub-portion 551b than the first sub-portion 551a.

In one or more embodiments, the first portion 552 may include the adhesive area a. In another example, the first portion 552 may be a portion of the end portion of the adhesive layer 550 including only the adhesive area a. The first portion 552 may bond neighboring components.

In one or more embodiments, the second portion 553 may be disposed between the folding portion 551 and the first portion 552. The second portion 553 may be an area including a combination of the adhesive area a and the non-adhesive area b. In another example, the second portion 453 may be an area disposed on the second region 430b of the support plate 430.

In one or more embodiments, the second portion 553 may include a fifth sub-portion 553a and a sixth sub-portion 553b. The fifth sub-portion 553a may be an area between the first sub-portion 551a and the third sub-portion 552a. The sixth sub-portion 553b may be an area between the second sub-portion 551b and the fourth sub-portion 552b.

In one or more embodiments, the second portion 553 may have a ratio of the adhesive area a per unit area increasing from the folding portion 551 toward the first portion 552. For example, the second portion 553 may have a relative ratio of the adhesive area a to the non-adhesive area b per unit area increasing from the folding portion 551 toward the first portion 552.

In one or more embodiments, the third portion 554 may be provided between the first sub-portion 551a and the second sub-portion 551b. The third portion 554 may have a ratio of the adhesive area a per unit area increasing or decreasing in a direction away from each of the first sub-portion 551a and the second sub-portion 551b.

For example, the third portion 554 may have a relative ratio of the adhesive area a to the non-adhesive area b per unit area increasing or decreasing from the first sub-portion 551a toward the second sub-portion 551b.

In one or more embodiments of the present disclosure, by changing the ratio of the adhesive area a of the second portion 553 and the third portion 554, the display module 500 may disperse stress applied to the display panel 510 or alleviate stress transmitted to the display panel 510. The adhesive layer 550 may disperse stress transmitted to the display panel 510 when the display module 500 is dropped or receives a shock so that the stress may not be concentrated, thereby reducing or preventing damage to the display module 500.

In one or more embodiments, since the adhesive layer 550 is disposed to face the support plate 530, a non-adhesive area b may be required in an area facing the lattice pattern 531. In the area where the adhesive area a and the non-adhesive area b adjoin, stress transmitted to the display panel 510 may be concentrated. The second portion 553 and the third portion 554 may include a combination of the adhesive area a and the non-adhesive area b, and may disperse the concentrated stress at a partial site.

For example, if the second portion 553 and the third portion 554 are omitted, stress transmitted to the display panel 510 may be concentrated at a site adjacent to the folding area F, causing pressure to be applied to or damage to the display panel 510.

In one or more embodiments of the present disclosure, the second portion 553 and the third portion 554 may disperse the stress concentrated at the connection site of the folding portion 551 and the first portion 552 and the connection site of the two folding portions 551 to a wide range, and may alleviate the stress applied to the display panel 510.

The description of the structures, shapes, and patterns of the second portion 553 and the third portion 554 according to one or more embodiments of the present disclosure may be understood with reference to the descriptions of the second portions 453, second portion 453-1, second portion 453-2, second portion 453-3, second portion 453-4, second portion 453-5, and second portion 453-6 of the adhesive layers 450, adhesive layer 450-1, adhesive layer 450-2, adhesive layer 450-3, adhesive layer 450-4, adhesive layer 450-5, and adhesive layer 450-6 provided above, and the above descriptions may apply substantially identically or similarly to the adhesive layer 550 of FIG. 12A and FIG. 12B.

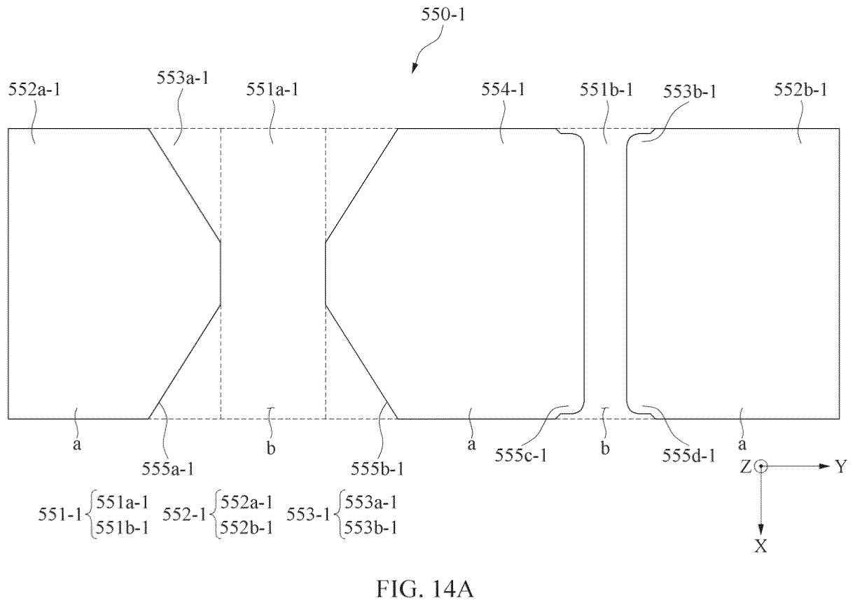

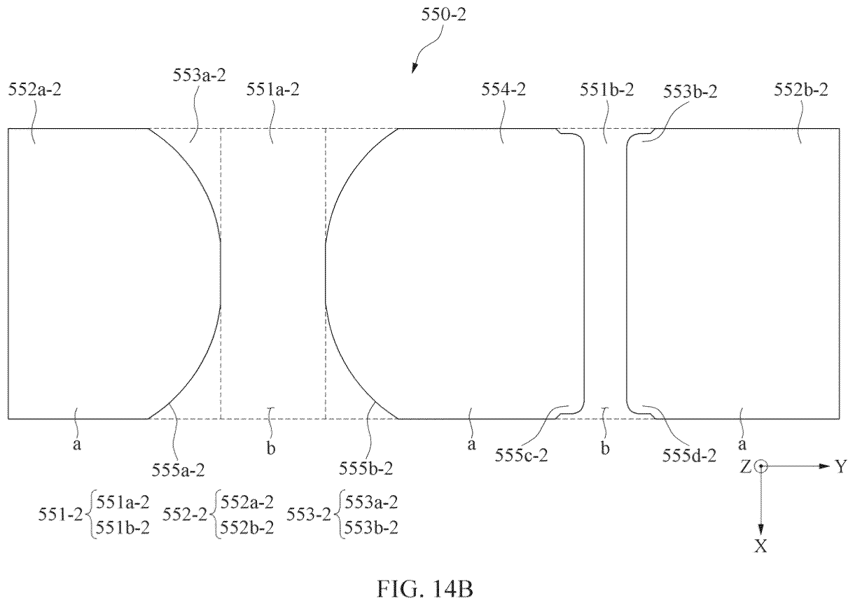

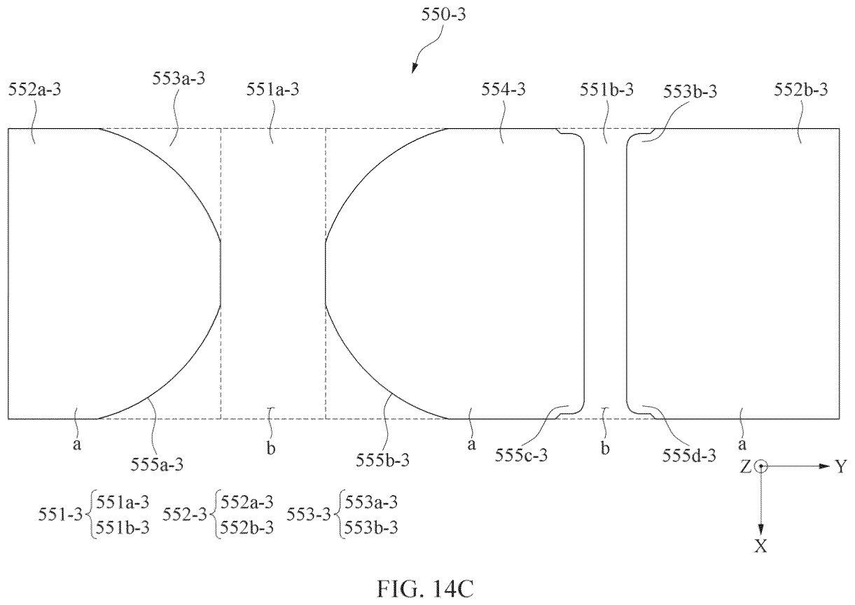

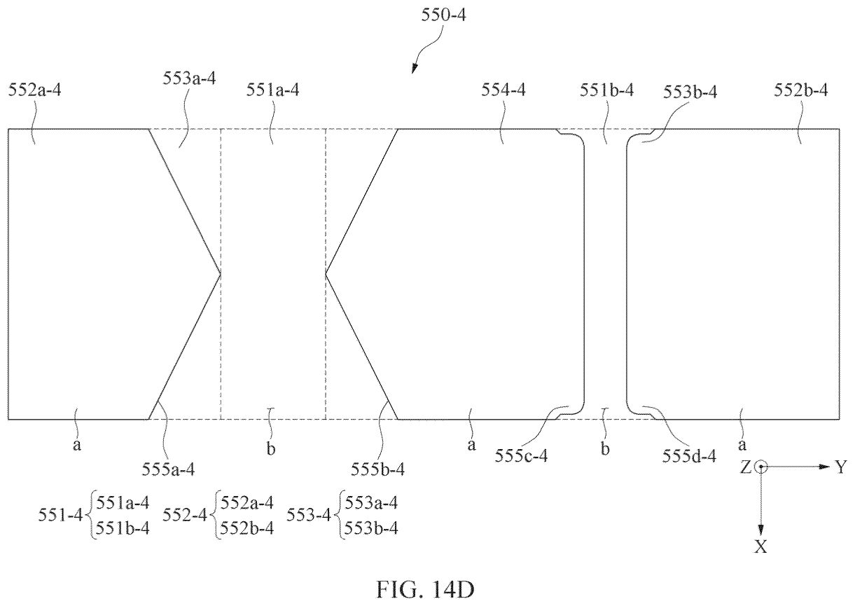

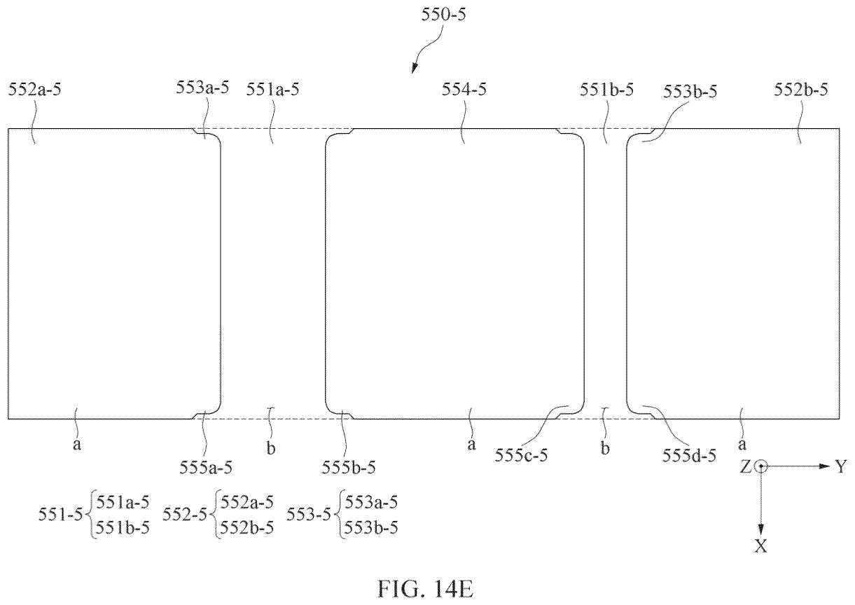

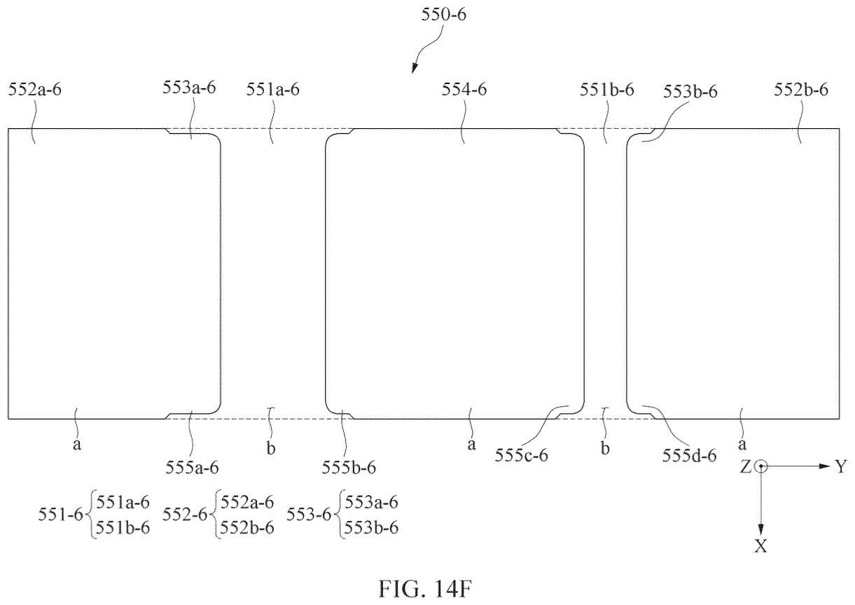

FIG. 14A, FIG. 14B, FIG. 14C, FIG. 14D, FIG. 14E, and FIG. 14F are plan views of adhesive layers, adhesive layer 550-1, adhesive layer 550-2, adhesive layer 550-3, adhesive layer 550-4, adhesive layer 550-5, and adhesive layer 550-6, according to one or more embodiments.

Referring to FIG. 14A, FIG. 14B, FIG. 14C, FIG. 14D, FIG. 14E, and FIG. 14F, adhesive layers, adhesive layer 550-1, adhesive layer 550-2, adhesive layer 550-3, adhesive layer 550-4, adhesive layer 550-5, and adhesive layer 550-6 (e.g., the adhesive layer 550 of FIGS. 12A and 12B) according to one or more embodiments may include second portions, second portion 553-1, second portion 553-2, second portion 553-3, second portion 553-4, second portion 553-5, and second portion 553-6, (e.g., the second portion 553 of FIG. 12B) and third portions, third portion 554-1, third portion 554-2, third portion 554-3, third portion 554-4, third portion 554-5, and third portion 554-6, (e.g., the third portion 554 of FIG. 12B) in various shapes and structures.

Hereinafter, the description provided above will not be repeated, and some configurations and structures of the adhesive layers, adhesive layer 550-1, adhesive layer 550-2, adhesive layer 550-3, adhesive layer 550-4, adhesive layer 550-5, and adhesive layer 550-6, may be replaced, added, or omitted within a range that those skilled in the art can easily understand by referring to the following drawings and description. Additionally, the features, or at least one configuration in the embodiments described above may be combined with the adhesive layers 550-1, 550-2, 550-3, 550-4, 550-5, and 550-6 unless technically obviously infeasible.

In one or more embodiments, the adhesive layers, adhesive layer 550-1, adhesive layer 550-2, adhesive layer 550-3, adhesive layer 550-4, adhesive layer 550-5, and adhesive layer 550-6, may include at least a portion of folding portions, folding portion 551-1, folding portion 551-2, folding portion 551-3, folding portion 551-4, folding portion 551-5, and folding portion 551-6, (e.g., the folding portion 551 of FIG. 12B), first portions, first portion 552-1, first portion 552-2, first portion 552-3, first portion 552-4, first portion 552-5, and first portion 552-6, (e.g., the first portion 552 of FIG. 12B), the second portions, second portion 553-1, second portion 553-2, second portion 553-3, second portion 553-4, second portion 553-5, and second portion 553-6, and the third portions, third portion 554-1, third portion 554-2, third portion 554-3, third portion 554-4, third portion 554-5, and third portion 554-6.

In one or more embodiments, the folding portions, folding portion 551-1, folding portion 551-2, folding portion 551-3, folding portion 551-4, folding portion 551-5, and folding portion 551-6, may include first sub-portions, first sub-portion 551a-1, first sub-portion 551a-2, first sub-portion 551a-3, first sub-portion 551a-4, first sub-portion 551a-5, and first sub-portion 551a-6, (e.g., the first sub-portion 551a of FIG. 12B) and second sub-portions, second sub-portion 551b-1, second sub-portion 551b-2, second sub-portion 551b-3, second sub-portion 551b-4, second sub-portion 551b-5, and second sub-portion 551b-6 (e.g., the second sub-portion 551b of FIG. 12B).

In one or more embodiments, the first portions, first portion 552-1, first portion 552-2, first portion 552-3, first portion 552-4, first portion 552-5, and first portion 552-6, may include third sub-portions, third sub-portion 552a-1, third sub-portion 552a-2, third sub-portion 552a-3, third sub-portion 552a-4, third sub-portion 552a-5, and third sub-portion 552a-6, (e.g., the third sub-portion 552a of FIG. 12B) and fourth sub-portions, fourth sub-portion 552b-1, fourth sub-portion 552b-2, fourth sub-portion 552b-3, fourth sub-portion 552b-4, fourth sub-portion 552b-5, and fourth sub-portion 552b-6, (e.g., the fourth sub-portion 552b of FIG. 12B).

In one or more embodiments, the second portions, second portion 553-1, second portion 553-2, second portion 553-3, second portion 553-4, second portion 553-5, and second portion 553-6, may include fifth sub-portions, fifth sub-portion 553a-1, fifth sub-portion 553a-2, fifth sub-portion 553a-3, fifth sub-portion 553a-4, fifth sub-portion 553a-5, and fifth sub-portion 553a-6, (e.g., the fifth sub-portion 553a of FIG. 12B) and sixth sub-portions, sixth sub-portion 553b-1, sixth sub-portion 553b-2, sixth sub-portion 553b-3, sixth sub-portion 553b-4, sixth sub-portion 553b-5, and sixth sub-portion 553b-6 (e.g., the sixth sub-portion 553b of FIG. 12B).

Hereinafter, in describing the adhesive layers, adhesive layer 550-1, adhesive layer 550-2, adhesive layer 550-3, adhesive layer 550-4, adhesive layer 550-5, and adhesive layer 550-6, the description provided above will not be repeated, and the above descriptions may apply substantially identically or similarly to the adhesive layers, adhesive layer 550-1, adhesive layer 550-2, adhesive layer 550-3, adhesive layer 550-4, adhesive layer 550-5, and adhesive layer 550-6 of FIG. 14A, FIG. 14B, FIG. 14C, FIG. 14D, FIG. 14E, and FIG. 14F.

Referring to FIG. 14A, the adhesive layer 550-1 may include a first boundary area 555a-1, a second boundary area 555b-1, a third boundary area 555c-1, and a fourth boundary area 555d-1. Each of the first boundary area 555a-1, the second boundary area 555b-1, the third boundary area 555c-1, and the fourth boundary area 555d-1 may be an area where an adhesive area a and a non-adhesive area b face each other.

In one or more embodiments, the first boundary area 555a-1 may be provided in the fifth sub-portion 553a-1. The first boundary area 555a-1 may be a line curved in a diagonal shape from the first sub-portion 551a-1 toward the third sub-portion 552a-1.

In one or more embodiments, by means of the first boundary area 555a-1, the fifth sub-portion 553a-1 may gradually increase the ratio of the adhesive area a from the first sub-portion 551a-1 toward the third sub-portion 552a-1.

In one or more embodiments, the second boundary area 555b-1 may be provided in the third portion 554-1 to be closer to the first sub-portion 551a-1 than the second sub-portion 551b-1. The first boundary area 555a-1 may be a line curved in a diagonal shape from the first sub-portion 551a-1 toward the second sub-portion 551b-1.

In one or more embodiments, by means of the second boundary area 555b-1, the third portion 554-1 may gradually increase the ratio of the adhesive area a from the first sub-portion 551a-1 toward the second sub-portion 551b-1.

For example, in the first boundary area 555a-1 and the second boundary area 555b-1, the width of the adhesive area a may gradually increase away from the first sub-portion 551a-1. In another example, in the first boundary area 555a-1 and the second boundary area 555b-1, the non-adhesive area b may have a pattern shape of a plurality of geometric structures in triangular shapes. Through the curved shapes of the first boundary area 555a-1 and the second boundary area 555b-1, the adhesive layer 550-1 may effectively disperse stress.

In one or more embodiments, the third boundary area 555c-1 may be provided in the third portion 554-1 to be closer to the second sub-portion 551b-1 than the first sub-portion 551a-1. The third boundary area 555c-1 may be formed at an end portion in the folding axis direction (e.g., the X-axis direction) adjacent to the second sub-portion 551b-1.

In one or more embodiments, the third boundary area 555c-1 may be formed in a shape in which the width of the non-adhesive area b gradually decreases from the second sub-portion 551b-1 toward the first sub-portion 551a-1, and may gradually increase the ratio of the adhesive area a.

In one or more embodiments, the fourth boundary area 555d-1 may be provided in the sixth sub-portion 553b-1. The fourth boundary area 555d-1 may be formed at an end portion in the folding axis direction adjacent to the second sub-portion 551b-1.

In one or more embodiments, the fourth boundary area 555d-1 may be formed in a shape in which the width of the non-adhesive area b gradually decreases from the second sub-portion 551b-1 toward the fourth sub-portion 552b-1, and may gradually increase the ratio of the adhesive area a.

In one or more embodiments, in the third boundary area 555c-1 and the fourth boundary area 555d-1, the width of the adhesive area a may gradually increase away from the second sub-portion 551b-1. In another example, in the first boundary area 555a-1 and the second boundary area 555b-1, the non-adhesive area b may have a pattern shape of a plurality of geometric structures in offset shapes formed at both end portions in the folding axis direction. Through the offset shapes of the first boundary area 555a-1 and the second boundary area 555b-1, the adhesive layer 550-1 may effectively disperse stress.

Referring to FIG. 14B, the adhesive layer 550-2 may include a first boundary area 555a-2, a second boundary area 555b-2, a third boundary area 555c-2, and a fourth boundary area 555d-2. Each of the first boundary area 555a-2, the second boundary area 555b-2, the third boundary area 555c-2, and the fourth boundary area 555d-2 may be an area where an adhesive area a and a non-adhesive area b face each other.

In one or more embodiments, the first boundary area 555a-2 may be provided in the fifth sub-portion 553a-2. The first boundary area 555a-2 may be a line curved in a semicircular shape from the first sub-portion 551a-2 toward the third sub-portion 552a-2.

In one or more embodiments, by means of the first boundary area 555a-2, the fifth sub-portion 553a-2 may gradually increase the ratio of the adhesive area a from the first sub-portion 551a-2 toward the third sub-portion 552a-2.

In one or more embodiments, the second boundary area 555b-2 may be provided in the third portion 554-2 to be closer to the first sub-portion 551a-2 than the second sub-portion 551b-2. The first boundary area 555a-2 may be a line curved in a semicircular shape from the first sub-portion 551a-2 toward the second sub-portion 551b-2.

In one or more embodiments, by means of the second boundary area 555b-2, the third portion 554-2 may gradually increase the ratio of the adhesive area a from the first sub-portion 551a-2 toward the second sub-portion 551b-2.

For example, in the first boundary area 555a-2 and the second boundary area 555b-2, the width of the adhesive area a may gradually increase away from the first sub-portion 551a-2. In another example, in the first boundary area 555a-2 and the second boundary area 555b-2, the adhesive area a may have a pattern shape of a geometric structure in a semicircular shape. Through the curved shapes of the first boundary area 555a-2 and the second boundary area 555b-2, the adhesive layer 550-2 may effectively disperse stress.

In one or more embodiments, the third boundary area 555c-2 may be provided in the third portion 554-2 to be closer to the second sub-portion 551b-2 than the first sub-portion 551a-2. The third boundary area 555c-2 may be formed at an end portion in the folding axis direction (e.g., the X-axis direction) adjacent to the second sub-portion 551b-2.

In one or more embodiments, the third boundary area 555c-2 may be formed in a shape in which the width of the non-adhesive area b gradually decreases from the second sub-portion 551b-2 toward the first sub-portion 551a-2, and may gradually increase the ratio of the adhesive area a.

In one or more embodiments, the fourth boundary area 555d-2 may be provided in the sixth sub-portion 553b-2. The fourth boundary area 555d-2 may be formed at an end portion in the folding axis direction adjacent to the second sub-portion 551b-2.

In one or more embodiments, the fourth boundary area 555d-2 may be formed in a shape in which the width of the non-adhesive area b gradually decreases from the second sub-portion 551b-2 toward the fourth sub-portion 552b-2, and may gradually increase the ratio of the adhesive area a.

In one or more embodiments, in the third boundary area 555c-2 and the fourth boundary area 555d-2, the width of the adhesive area a may gradually increase away from the second sub-portion 551b-2. In another example, in the first boundary area 555a-2 and the second boundary area 555b-2, the non-adhesive area b may have a pattern shape of a plurality of geometric structures in offset shapes formed at both end portions in the folding axis direction. Through the offset shapes of the first boundary area 555a-2 and the second boundary area 555b-2, the adhesive layer 550-2 may effectively disperse stress.

Referring to FIG. 14C, the adhesive layer 550-3 may include a first boundary area 555a-3, a second boundary area 555b-3, a third boundary area 555c-3, and a fourth boundary area 555d-3. Each of the first boundary area 555a-3, the second boundary area 555b-3, the third boundary area 555c-3, and the fourth boundary area 555d-3 may be an area where an adhesive area a and a non-adhesive area b face each other.

In one or more embodiments, the first boundary area 555a-3 may be provided in the fifth sub-portion 553a-3. The first boundary area 555a-3 may be a line curved in a semi-oval shape from the first sub-portion 551a-3 toward the third sub-portion 552a-3.

In one or more embodiments, by means of the first boundary area 555a-3, the fifth sub-portion 553a-3 may gradually increase the ratio of the adhesive area a from the first sub-portion 551a-3 toward the third sub-portion 552a-3.

In one or more embodiments, the second boundary area 555b-3 may be provided in the third portion 554-3 to be closer to the first sub-portion 551a-3 than the second sub-portion 551b-3. The first boundary area 555a-3 may be a line curved in a semi-oval shape from the first sub-portion 551a-3 toward the second sub-portion 551b-3.

In one or more embodiments, by means of the second boundary area 555b-3, the third portion 554-3 may gradually increase the ratio of the adhesive area a from the first sub-portion 551a-3 toward the second sub-portion 551b-3.

For example, in the first boundary area 555a-3 and the second boundary area 555b-3, the width of the adhesive area a may gradually increase away from the first sub-portion 551a-3. In another example, in the first boundary area 555a-3 and the second boundary area 555b-3, the adhesive area a may have a pattern shape of a geometric structure in a semi-oval shape. Through the curved shapes of the first boundary area 555a-3 and the second boundary area 555b-3, the adhesive layer 550-3 may effectively disperse stress.

In one or more embodiments, the third boundary area 555c-3 may be provided in the third portion 554-3 to be closer to the second sub-portion 551b-3 than the first sub-portion 551a-3. The third boundary area 555c-3 may be formed at an end portion in the folding axis direction (e.g., the X-axis direction) adjacent to the second sub-portion 551b-3.

In one or more embodiments, the third boundary area 555c-3 may be formed in a shape in which the width of the non-adhesive area b gradually decreases from the second sub-portion 551b-3 toward the first sub-portion 551a-3, and may gradually increase the ratio of the adhesive area a.

In one or more embodiments, the fourth boundary area 555d-3 may be provided in the sixth sub-portion 553b-3. The fourth boundary area 555d-3 may be formed at an end portion in the folding axis direction adjacent to the second sub-portion 551b-3.

In one or more embodiments, the fourth boundary area 555d-3 may be formed in a shape in which the width of the non-adhesive area b gradually decreases from the second sub-portion 551b-3 toward the fourth sub-portion 552b-3, and may gradually increase the ratio of the adhesive area a.

In one or more embodiments, in the third boundary area 555c-3 and the fourth boundary area 555d-3, the width of the adhesive area a may gradually increase away from the second sub-portion 551b-3. In another example, in the third boundary area 555c-3 and the fourth boundary area 555d-3, the non-adhesive area b may have a pattern shape of a plurality of geometric structures in offset shapes formed at both end portions in the folding axis direction. Through the offset shapes of the third boundary area 555c-3 and the fourth boundary area 555d-3, the adhesive layer 550-3 may effectively disperse stress.

Referring to FIG. 14D, the adhesive layer 550-4 may include a first boundary area 555a-4, a second boundary area 555b-4, a third boundary area 555c-4, and a fourth boundary area 555d-4. Each of the first boundary area 555a-4, the second boundary area 555b-4, the third boundary area 555c-4, and the fourth boundary area 555d-4 may be an area where an adhesive area a and a non-adhesive area b face each other.

In one or more embodiments, the first boundary area 555a-4 may be provided in the fifth sub-portion 553a-4. The first boundary area 555a-4 may be a line curved in a diagonal shape from the first sub-portion 551a-4 toward the third sub-portion 552a-4.

In one or more embodiments, by means of the first boundary area 555a-4, the fifth sub-portion 553a-4 may gradually increase the ratio of the adhesive area a from the first sub-portion 551a-4 toward the third sub-portion 552a-4.

In one or more embodiments, the second boundary area 555b-4 may be provided in the third portion 554-4 to be closer to the first sub-portion 551a-4 than the second sub-portion 551b-4. The first boundary area 555a-4 may be a line curved in a diagonal shape from the first sub-portion 551a-4 toward the second sub-portion 551b-4.

In one or more embodiments, by means of the second boundary area 555b-4, the third portion 554-4 may gradually increase the ratio of the adhesive area a from the first sub-portion 551a-4 toward the second sub-portion 551b-4.

For example, in the first boundary area 555a-4 and the second boundary area 555b-4, the width of the adhesive area a may gradually increase away from the first sub-portion 551a-4. In another example, in the first boundary area 555a-4 and the second boundary area 555b-4, the adhesive area a may have a pattern shape of a geometric structure in a triangular shape. Through the curved shapes of the first boundary area 555a-4 and the second boundary area 555b-4, the adhesive layer 550-4 may effectively disperse stress.

In one or more embodiments, the third boundary area 555c-4 may be provided in the third portion 554-4 to be closer to the second sub-portion 551b-4 than the first sub-portion 551a-4. The third boundary area 555c-4 may be formed at an end portion in the folding axis direction (e.g., the X-axis direction) adjacent to the second sub-portion 551b-4.

In one or more embodiments, the third boundary area 555c-4 may be formed in a shape in which the width of the non-adhesive area b gradually decreases from the second sub-portion 551b-4 toward the first sub-portion 551a-4, and may gradually increase the ratio of the adhesive area a.

In one or more embodiments, the fourth boundary area 555d-4 may be provided in the sixth sub-portion 553b-4. The fourth boundary area 555d-4 may be formed at an end portion in the folding axis direction adjacent to the second sub-portion 551b-4.

In one or more embodiments, the fourth boundary area 555d-4 may be formed in a shape in which the width of the non-adhesive area b gradually decreases from the second sub-portion 551b-4 toward the fourth sub-portion 552b-4, and may gradually increase the ratio of the adhesive area a.

In one or more embodiments, in the third boundary area 555c-4 and the fourth boundary area 555d-4, the width of the adhesive area a may gradually increase away from the second sub-portion 551b-4. In another example, in the first boundary area 555a-4 and the second boundary area 555b-4, the non-adhesive area b may have a pattern shape of a plurality of geometric structures in offset shapes formed at both end portions in the folding axis direction. Through the offset shapes of the third boundary area 555c-4 and the fourth boundary area 555d-4, the adhesive layer 550-4 may effectively disperse stress.

Referring to FIG. 14E, the adhesive layer 550-5 may include a first boundary area 555a-5, a second boundary area 555b-5, a third boundary area 555c-5, and a fourth boundary area 555d-5. Each of the first boundary area 555a-5, the second boundary area 555b-5, the third boundary area 555c-5, and the fourth boundary area 555d-5 may be an area where an adhesive area a and a non-adhesive area b face each other.

In one or more embodiments, the first boundary area 555a-5 may be provided in the fifth sub-portion 553a-5. The first boundary area 555a-5 may be formed at an end portion in the folding axis direction (e.g., the X-axis direction) adjacent to the fifth sub-portion 553a-5.

In one or more embodiments, the first boundary area 555a-5 may be formed in a shape in which the width of the non-adhesive area b gradually decreases from the first sub-portion 551a-5 toward the third sub-portion 552a-5, and may gradually increase the ratio of the adhesive area a.

In one or more embodiments, the second boundary area 555b-5 may be provided in the third portion 554-5 to be closer to the first sub-portion 551a-5 than the second sub-portion 551b-5. The second boundary area 555b-5 may be formed at an end portion in the folding axis direction adjacent to the fifth sub-portion 553a-5.

In one or more embodiments, the second boundary area 555b-5 may be formed in a shape in which the width of the non-adhesive area b gradually decreases from the first sub-portion 551a-5 toward the second sub-portion 551b-5, and may gradually increase the ratio of the adhesive area a.

In one or more embodiments, the third boundary area 555c-5 may be provided in the third portion 554-5 to be closer to the second sub-portion 551b-5 than the first sub-portion 551a-5. The third boundary area 555c-5 may be formed at an end portion in the folding axis direction (e.g., the X-axis direction) adjacent to the second sub-portion 551b-5.

In one or more embodiments, the third boundary area 555c-5 may be formed in a shape in which the width of the non-adhesive area b gradually decreases from the second sub-portion 551b-5 toward the first sub-portion 551a-5, and may gradually increase the ratio of the adhesive area a.

In one or more embodiments, the fourth boundary area 555d-5 may be provided in the sixth sub-portion 553b-5. The fourth boundary area 555d-5 may be formed at an end portion in the folding axis direction adjacent to the second sub-portion 551b-5.

In one or more embodiments, the fourth boundary area 555d-5 may be formed in a shape in which the width of the non-adhesive area b gradually decreases from the second sub-portion 551b-5 toward the fourth sub-portion 552b-5, and may gradually increase the ratio of the adhesive area a.

In one or more embodiments, in the first boundary area 555a-5, the second boundary area 555b-5, the third boundary area 555c-5, and the fourth boundary area 555d-5, the width of the adhesive area a may gradually increase away from the second sub-portion 551b-5. In another example, in the first boundary area 555a-5 and the second boundary area 555b-5, the non-adhesive area b may have a pattern shape of a plurality of geometric structures in offset shapes formed at both end portions in the folding axis direction. Through the offset shapes of the first boundary area 555a-5, the second boundary area 555b-5, the third boundary area 555c-5, and the fourth boundary area 555d-5, the adhesive layer 550-5 may effectively disperse stress.

Referring to FIG. 14F, the adhesive layer 550-6 may include a first boundary area 555a-6, a second boundary area 555b-6, a third boundary area 555c-6, and a fourth boundary area 555d-6. Each of the first boundary area 555a-6, the second boundary area 555b-6, the third boundary area 555c-6, and the fourth boundary area 555d-6 may be an area where an adhesive area a and a non-adhesive area b face each other.

In one or more embodiments, the first boundary area 555a-6 may be provided in the fifth sub-portion 553a-6. The first boundary area 555a-6 may be formed at an end portion in the folding axis direction (e.g., the X-axis direction) adjacent to the fifth sub-portion 553a-6.

In one or more embodiments, the first boundary area 555a-6 may be formed in a shape in which the width of the non-adhesive area b gradually decreases from the first sub-portion 551a-6 toward the third sub-portion 552a-6, and may gradually increase the ratio of the adhesive area a.

In one or more embodiments, the second boundary area 555b-6 may be provided in the third portion 554-6 to be closer to the first sub-portion 551a-6 than the second sub-portion 551b-6. The second boundary area 555b-6 may be formed at an end portion in the folding axis direction adjacent to the fifth sub-portion 553a-6.

In one or more embodiments, the second boundary area 555b-6 may be formed in a shape in which the width of the non-adhesive area b gradually decreases from the first sub-portion 551a-6 toward the second sub-portion 551b-6, and may gradually increase the ratio of the adhesive area a.

In one or more embodiments, the third boundary area 555c-6 may be provided in the third portion 554-6 to be closer to the second sub-portion 551b-6 than the first sub-portion 551a-6. The third boundary area 555c-6 may be formed at an end portion in the folding axis direction (e.g., the X-axis direction) adjacent to the second sub-portion 551b-6.

In one or more embodiments, the third boundary area 555c-6 may be formed in a shape in which the width of the non-adhesive area b gradually decreases from the second sub-portion 551b-6 toward the first sub-portion 551a-6, and may gradually increase the ratio of the adhesive area a.

In one or more embodiments, the fourth boundary area 555d-6 may be provided in the sixth sub-portion 553b-6. The fourth boundary area 555d-6 may be formed at an end portion in the folding axis direction adjacent to the second sub-portion 551b-6.

In one or more embodiments, the fourth boundary area 555d-6 may be formed in a shape in which the width of the non-adhesive area b gradually decreases from the second sub-portion 551b-6 toward the fourth sub-portion 552b-6, and may gradually increase the ratio of the adhesive area a.

In one or more embodiments, in the first boundary area 555a-6, the second boundary area 555b-6, the third boundary area 555c-6, and the fourth boundary area 555d-6, the width of the adhesive area a may gradually increase away from the second sub-portion 551b-6. In another example, in the first boundary area 555a-6 and the second boundary area 555b-6, the non-adhesive area b may have a pattern shape of a plurality of geometric structures in offset shapes formed at both end portions in the folding axis direction. Through the offset shapes of the first boundary area 555a-6, the second boundary area 555b-6, the third boundary area 555c-6, and the fourth boundary area 555d-6, the adhesive layer 550-6 may effectively disperse stress.

In one or more embodiments, the length, area, and shape of at least one of the first boundary area 555a-6, the second boundary area 555b-6, the third boundary area 555c-6, and the fourth boundary area 555d-6 may be different from those of another.

For example, the first sub-portion 551a-6 may have a larger folding area, or may receive a greater force during a folding operation, than the second sub-portion 551b-6. The first boundary area 555a-6 and the second boundary area 555b-6 may need to disperse a relatively large magnitude of stress compared to the third boundary area 555c-6 and the fourth boundary area 555d-6 and thus, may be relatively large in length and area.

In one or more embodiments, the first boundary area 555a-6 may need to disperse a relatively large magnitude of stress compared to the second boundary area 555b-6 and thus, may be relatively large in length and area.

For example, the first boundary area 555a-6 may receive a greater force during a folding operation than the second sub-portion 555b-6. In another example, since the third sub-portion 552a-6 is present on the outer side of the adhesive layer 550-6, greater stress may be exerted on the fifth sub-portion 553a-6.

A display module 400 according to one or more embodiments may include a display panel 410, a support plate 430 supporting the display panel 410, the support plate 430 including a bendable region including a lattice pattern 431, and an adhesive layer 450, adhesive layer 450-1, adhesive layer 450-2, adhesive layer 450-3, adhesive layer 450-4, adhesive layer 450-5, or adhesive layer 450-6 disposed between the display panel 410 and the support plate 430. In one or more embodiments, an adhesive area of the adhesive layer 450, adhesive layer 450-1, adhesive layer 450-2, adhesive layer 450-3, adhesive layer 450-4, adhesive layer 450-5, or adhesive layer 450-6 may be omitted from the bendable region of the support plate 430. The adhesive layer 450, adhesive layer 450-1, adhesive layer 450-2, adhesive layer 450-3, adhesive layer 450-4, adhesive layer 450-5, or adhesive layer 450-6 may include a first portion 452, first portion 452-1, first portion 452-2, first portion 452-3, first portion 452-4, first portion 452-5, or first portion 452-6, including an adhesive area a, disposed on a first region 430a of the support plate 430 spaced apart from the bendable region in a first direction D1, and a second portion 453, second portion 453-1, second portion 453-2, second portion 453-3, second portion 453-4, second portion 453-5, or second portion 453-6 disposed on a second region 430b of the support plate 430 between the first region 430a of the support plate 430 and the bendable region, the second portion 453, second portion 453-1, second portion 453-2, second portion 453-3, second portion 453-4, second portion 453-5, or second portion 453-6 including a combination of an adhesive area a and a non-adhesive area b or non-adhesive area b′ and having a ratio of the adhesive area a per unit area increasing in the first direction D1.

In one or more embodiments, in the second portion 453, second portion 453-1, second portion 453-2, second portion 453-3, second portion 453-4, or second portion 453-5, the adhesive area a may include a plurality of geometric structures, geometric structure G1, geometric structure G2, or geometric structure G3, a size of each of the plurality of geometric structures, geometric structure G1, geometric structure G2, or geometric structure G3, may increase in the first direction D1, and the non-adhesive area b or non-adhesive area b′ may at least partially surround each of the plurality of geometric structures, geometric structure G1, geometric structure G2, or geometric structure G3.

A display module 400 according to one or more embodiments may include a display panel 410, a support plate 430 supporting the display panel 410, and an adhesive layer 450, adhesive layer 450-1, adhesive layer 450-2, adhesive layer 450-3, adhesive layer 450-4, adhesive layer 450-5, or adhesive layer 450-6 disposed between the display panel 410 and the support plate 430, the adhesive layer 450, adhesive layer 450-1, adhesive layer 450-2, adhesive layer 450-3, adhesive layer 450-4, adhesive layer 450-5, or adhesive layer 450-6 including an adhesive area a and a non-adhesive area b or non-adhesive area b′. In one or more embodiments, the display module 400 may include a bendable folding area F. In one or more embodiments, the adhesive layer 450, adhesive layer 450-1, adhesive layer 450-2, adhesive layer 450-3, adhesive layer 450-4, adhesive layer 450-5, or adhesive layer 450-6 may include a folding portion 451, folding portion 451-1, folding portion 451-2, folding portion 451-3, folding portion 451-4, folding portion 451-5, or folding portion 451-6 overlapping the folding area F in a direction facing the display panel 410 and including a non-adhesive area b or non-adhesive area b′, a first portion 452, first portion 452-1, first portion 452-2, first portion 452-3, first portion 452-4, first portion 452-5, or first portion 452-6 spaced apart from the folding portion 451, folding portion 451-1, folding portion 451-2, folding portion 451-3, folding portion 451-4, folding portion 451-5, or folding portion 451-6 in a first direction D1, the first portion 452, first portion 452-1, first portion 452-2, first portion 452-3, first portion 452-4, first portion 452-5, or first portion 452-6 including an adhesive area a, and a second portion 453, second portion 453-1, second portion 453-2, second portion 453-3, second portion 453-4, second portion 453-5, or second portion 453-6 disposed between the folding portion 451, folding portion 451-1, folding portion 451-2, folding portion 451-3, folding portion 451-4, folding portion 451-5, or folding portion 451-6 and the first portion 452, first portion 452-1, first portion 452-2, first portion 452-3, first portion 452-4, first portion 452-5, or first portion 452-6, the second portion 453, second portion 453-1, second portion 453-2, second portion 453-3, second portion 453-4, second portion 453-5, or second portion 453-6 including a combination of an adhesive area a and a non-adhesive area b or non-adhesive area b′. In one or more embodiments, the second portion 453, second portion 453-1, second portion 453-2, second portion 453-3, second portion 453-4, second portion 453-5, or second portion 453-6 having a ratio of the adhesive area a per unit area increasing in the first direction D1 may be included.

In one or more embodiments, the adhesive area a may include an adhesive material. In one or more embodiments, the non-adhesive area b may include an open space.

In one or more embodiments, in the second portion 453, second portion 453-2, second portion 453-3, second portion 453-4, or second portion 453-5, the adhesive area a may be formed in a pattern shape in which a plurality of geometric structures, geometric structure G1, geometric structure G2, or geometric structure G3, are arranged. In one or more embodiments, the non-adhesive area b or non-adhesive area b′ may be formed in a shape surrounding each of the plurality of geometric structures, geometric structure G1, geometric structure G2, or geometric structure G3.

In one or more embodiments, the second portion 453, second portion 453-2, second portion 453-3, or second portion 453-5 may have a pattern shape in which the area of each of the plurality of geometric structures, geometric structure G1, geometric structure G2, or geometric structure G3, of the adhesive area a increases in the first direction D1.

In one or more embodiments, the plurality of geometric structures, geometric structure G1, geometric structure G2, or geometric structure G3 may be formed in polygonal shapes such as quadrangular, hexagonal, or octagonal shapes.

In one or more embodiments, the plurality of geometric structures G2 may be formed in circular or oval shapes.

In one or more embodiments, the second portion 453-1 or second portion 453-6 may include an edge area 455 or edge area 455-6 provided at an end portion in a second direction D2 perpendicular to the first direction D1 and formed in a shape in which the width of the non-adhesive area b or non-adhesive area b′ gradually decreases in the first direction D1.

In one or more embodiments, the edge area 455 or edge area 455-6 may include a boundary line L where the adhesive area a and the non-adhesive area b or non-adhesive area b′ face each other, and the boundary line L may be in a shape curved in the first direction D1.

In one or more embodiments, the second portion 453-1, second portion 453-4, second portion 453-5, or second portion 453-6 may have a ratio of the adhesive area a per unit area gradually increasing from an end portion in a second direction D2 perpendicular to the first direction D1 toward the center of the second portion 453-1, second portion 453-4, second portion 453-5, or second portion 453-6.

In one or more embodiments, in the second portion 453, second portion 453-2, second portion 453-3, second portion 453-4, or second portion 453-5, the adhesive area a may be formed in a pattern shape in which a plurality of geometric structures, geometric structure G1, geometric structure G2, or geometric structure G3, are arranged to be spaced apart from each other. In one or more embodiments, the non-adhesive area b or non-adhesive area b′ may be formed as a spaced area between the plurality of geometric structures, geometric structure G1, geometric structure G2, or geometric structure G3. In one or more embodiments, in the second portion 453, second portion 453-2, second portion 453-3, second portion 453-4, or second portion 453-5, an interval between the plurality of geometric structures, geometric structure G1, geometric structure G2, or geometric structure G3, may decrease in the first direction D1.

In one or more embodiments, in the second portion 453-4 or second portion 453-5, the adhesive area a may be formed in a pattern shape in which a plurality of geometric structures, geometric structure G1, geometric structure G2, or geometric structure G3, are arranged to be spaced apart from each other. In one or more embodiments, the non-adhesive area b or non-adhesive area b′ may be formed as a spaced area between the plurality of geometric structures, geometric structure G1, geometric structure G2, or geometric structure G3. In one or more embodiments, in the second portion 453-4 or second portion 453-5, from an end portion in the second direction D2 perpendicular to the first direction D1 toward the center of the second portion 453-4 or second portion 453-5, the interval between the plurality of geometric structures, geometric structure G1, geometric structure G2, or geometric structure G3, may decrease.

In one or more embodiments, the adhesive area a may include an adhesive material. In one or more embodiments, the non-adhesive area b′ may include an adhesive material and a non-adhesive material that covers at least one surface of the adhesive material.

In one or more embodiments, the non-adhesive area b of the second portion 453-6 may include a first non-adhesive portion b1 including an open space and a second non-adhesive portion b2 including a non-adhesive material.

In one or more embodiments, in the second portion 453-6, the non-adhesive area b or non-adhesive area b′ may be formed in a pattern shape in which a plurality of geometric structures Gb are arranged. In one or more embodiments, the adhesive area a may be formed in a shape surrounding each of the plurality of geometric structures Gb.

In one or more embodiments, the second portion 453-6 may have a pattern shape in which the area of each of the plurality of geometric structures Gb of the non-adhesive area b or non-adhesive area b′ decreases in the first direction D1.

In one or more embodiments, a bendable electronic device 401 may include the display module 400 according to one or more embodiments, and a housing structure 403 supporting the display module 400 in a foldable manner.

In one or more embodiments, the display module 400 may include a display panel 410, a support plate 430 supporting the display panel 410, the support plate 430 including a bendable region including a lattice pattern 431, and an adhesive layer 450-1 or adhesive layer 450-6 disposed between the display panel 410 and the support plate 430, the adhesive layer 450-1 or adhesive layer 450-6 including an adhesive area a and a non-adhesive area b or non-adhesive area b′. The adhesive area a of the adhesive layer 450-1 or adhesive layer 450-6 may be omitted from the bendable region of the support plate 430. The adhesive layer 450-1 or adhesive layer 450-6 may include a first portion 452-1 or first portion 452-6, including an adhesive area a, disposed on a first region 430a of the support plate 430 spaced apart from the bendable region of the support plate 430 in a first direction D1, and a second portion 453-1 or second portion 453-6 disposed on a second region 430b of the support plate 430 between the first region 430a of the support plate 430 and the bendable region, the second portion 453-1 or second portion 453-6 including the non-adhesive area b or non-adhesive area b′ at both end portions in a second direction D2 perpendicular to the first direction D1, and the adhesive area a between the end portions in the second direction D2.

In one or more embodiments, a display module 400 may include a display panel 410, a support plate 430 supporting the display panel 410, and an adhesive layer 450, adhesive layer 450-1, adhesive layer 450-2, adhesive layer 450-3, adhesive layer 450-4, adhesive layer 450-5, or adhesive layer 450-6 disposed between the display panel 410 and the support plate 430, the adhesive layer 450-1 or 450-6 including an adhesive area a and a non-adhesive area b or non-adhesive area b′. In one or more embodiments, the display module 400 may include a bendable folding area F. In one or more embodiments, the adhesive layer 450-1 or adhesive layer 450-6 may include a folding portion 451-1 or folding portion 451-6 overlapping the folding area F in a direction facing the display panel 410 and including a non-adhesive area b or non-adhesive area b′, a first portion 452-1 or first portion 452-6 spaced apart from the folding portion 451-1 or folding portion 451-6 in a first direction D1, the first portion 452-1 or first portion 452-6 including an adhesive area a, and a second portion 453-1 or second portion 453-6 disposed between the folding portion 451-1 or folding portion 451-6 and the first portion 452-1 or first portion 452-6, the second portion 453-1 or second portion 453-6 including a non-adhesive area b or non-adhesive area b′ at both end portions in a second direction D1 perpendicular to the first direction D1. In one or more embodiments, the second portion 453-1 or second portion 453-6 including the adhesive area a may be included between the end portions in the second direction D1.

In one or more embodiments, the second portion 453-1 or second portion 453-6 may include an edge area 455 or edge area 455-6 provided at the end portions in the second direction D2 and formed in a shape in which the width of the non-adhesive area b or non-adhesive area b′ gradually decreases in the first direction D1.

In one or more embodiments, the edge area 455 or edge area 455-6 may include a boundary line where the adhesive area a and the non-adhesive area b or non-adhesive area b′ face each other, and the boundary line may be in a shape curved in the first direction D1.

In one or more embodiments, an electronic device 401 may include a housing structure 403 forming an exterior, and a display module 400 including a bendable folding area F, and coupled to the housing structure 403 for at least a partial area thereof to be visually exposed. In one or more embodiments, the display module 400 may include a display panel 410, a support plate 430 supporting the display panel 410, and an adhesive layer 450, adhesive layer 450-1, adhesive layer 450-2, adhesive layer 450-3, adhesive layer 450-4, adhesive layer 450-5, or adhesive layer 450-6 disposed between the display panel 410 and the support plate 430, the adhesive layer 450, adhesive layer 450-1, adhesive layer 450-2, adhesive layer 450-3, adhesive layer 450-4, adhesive layer 450-5, or adhesive layer 450-6 including an adhesive area a and a non-adhesive area b or non-adhesive area b′. In one or more embodiments, the adhesive layer 450, adhesive layer 450-1, adhesive layer 450-2, adhesive layer 450-3, adhesive layer 450-4, adhesive layer 450-5, or adhesive layer 450-6 may include a folding portion 451, folding portion 451-1, folding portion 451-2, folding portion 451-3, folding portion 451-4, folding portion 451-5, or folding portion 451-6 overlapping the folding area F in a direction facing the display panel 410 and including a non-adhesive area b or non-adhesive area b′, a first portion 452, first portion 452-1, first portion 452-2, first portion 452-3, first portion 452-4, first portion 452-5, or first portion 452-6 spaced apart from the folding portion 451, folding portion 451-1, folding portion 451-2, folding portion 451-3, folding portion 451-4, folding portion 451-5, or folding portion 451-6 in a first direction D1, the first portion 452, first portion 452-1, first portion 452-2, first portion 452-3, first portion 452-4, first portion 452-5, or first portion 452-6 including an adhesive area a, and a second portion 453, second portion 453-1, second portion 453-2, second portion 453-3, second portion 453-4, second portion 453-5, or second portion 453-6 disposed between the folding portion 451, folding portion 451-1, folding portion 451-2, folding portion 451-3, folding portion 451-4, folding portion 451-5, or folding portion 451-6 and the first portion 452, first portion 452-1, first portion 452-2, first portion 452-3, first portion 452-4, first portion 452-5, or first portion 452-6, the second portion 453, second portion 453-1, second portion 453-2, second portion 453-3, second portion 453-4, second portion 453-5, or second portion 453-6 including an adhesive area a and a non-adhesive area b or non-adhesive area b′. In one or more embodiments, the second portion 453, second portion 453-1, second portion 453-2, second portion 453-3, second portion 453-4, second portion 453-5, or second portion 453-6 having a width of the non-adhesive area b or non-adhesive area b′ decreasing in the first direction D1 may be included.

In one or more embodiments, an electronic device 501 may include a housing structure 502 forming an exterior, and a display module 500 including a plurality of bendable folding areas, first filing area F1 and second folding area F2, and coupled to the housing structure 502 for at least a partial area thereof to be visually exposed. In one or more embodiments, the display module 500 may include a display panel 510, a support plate 530 supporting the display panel 510, the support plate 530 including a bendable region including a lattice pattern 531 and overlapping the bendable folding areas, first filing area F1 and second folding area F2, and an adhesive layer 550, adhesive layer 550-1, adhesive layer 550-2, adhesive layer 550-3, adhesive layer 550-4, adhesive layer 550-5, or adhesive layer 550-6 disposed between the display panel 510 and the support plate 530, the adhesive layer 550, adhesive layer 550-1, adhesive layer 550-2, adhesive layer 550-3, adhesive layer 550-4, adhesive layer 550-5, or adhesive layer 550-6 including an adhesive area a and a non-adhesive area b or non-adhesive area b′. In one or more embodiments, the adhesive area a of the adhesive layer 550, adhesive layer 550-1, adhesive layer 550-2, adhesive layer 550-3, adhesive layer 550-4, adhesive layer 550-5, or adhesive layer 550-6 may be omitted from the bendable region of the support plate 530. In one or more embodiments, the adhesive layer 550, adhesive layer 550-1, adhesive layer 550-2, adhesive layer 550-3, adhesive layer 550-4, adhesive layer 550-5, or adhesive layer 550-6 may include a first portion 552, first portion 552-1, first portion 552-2, first portion 552-3, first portion 552-4, first portion 552-5, or first portion 552-6, including an adhesive area a, disposed on a first region 530a of the support plate 530 spaced apart from the bendable region in a first direction D1, a second portion 553, second portion 553-1, second portion 553-2, second portion 553-3, second portion 553-4, second portion 553-5, or second portion 553-6 disposed on a second region 530b of the support plate 530 between the first region 530a of the support plate 530 and the bendable region, the second portion 553, second portion 553-1, second portion 553-2, second portion 553-3, second portion 553-4, second portion 553-5, or second portion 553-6 including the adhesive area a and the non-adhesive area b or non-adhesive area b′ and having a ratio of the adhesive area a per unit area increasing from the bendable region toward the first portion 552, first portion 552-1, first portion 552-2, first portion 552-3, first portion 552-4, first portion 552-5, or first portion 552-6, and a third portion 554, third portion 554-1, third portion 554-2, third portion 554-3, third portion 554-4, third portion 554-5, or third portion 554-6 disposed between the plurality of folding areas, first filing area F1 and second folding area F2, and having a ratio of the adhesive area a per unit area increasing in a direction away from each of the plurality of folding areas, first filing area F1 and second folding area F2.

In one or more embodiments, an electronic device 501 may include a housing structure 502 forming an exterior, and a display module 500 including a plurality of bendable folding areas, first filing area F1 and second folding area F2, and coupled to the housing structure 502 for at least a partial area thereof to be visually exposed. In one or more embodiments, the display module 500 may include a display panel 510, a support plate 530 supporting the display panel 510, and an adhesive layer 550, adhesive layer 550-1, adhesive layer 550-2, adhesive layer 550-3, adhesive layer 550-4, adhesive layer 550-5, or adhesive layer 550-6 disposed between the display panel 510 and the support plate 530, the adhesive layer 550, adhesive layer 550-1, adhesive layer 550-2, adhesive layer 550-3, adhesive layer 550-4, adhesive layer 550-5, or adhesive layer 550-6 including an adhesive area a and a non-adhesive area b or non-adhesive area b′. In one or more embodiments, the adhesive layer 550, adhesive layer 550-1, adhesive layer 550-2, adhesive layer 550-3, adhesive layer 550-4, adhesive layer 550-5, or adhesive layer 550-6 may include a folding portion 551, folding portion 551-1, folding portion 551-2, folding portion 551-3, folding portion 551-4, folding portion 551-5, or folding portion 551-6 facing each of the plurality of folding areas, first filing area F1 and second folding area F2, in a direction facing the display panel 510 and including a non-adhesive area b or non-adhesive area b′, a first portion 552, first portion 552-1, first portion 552-2, first portion 552-3, first portion 552-4, first portion 552-5, or first portion 552-6 spaced apart from the folding portion 551, folding portion 551-1, folding portion 551-2, folding portion 551-3, folding portion 551-4, folding portion 551-5, or folding portion 551-6, the first portion 552, first portion 552-1, first portion 552-2, first portion 552-3, first portion 552-4, first portion 552-5, or first portion 552-6 including an adhesive area a, and a second portion 553, second portion 553-1, second portion 553-2, second portion 553-3, second portion 553-4, second portion 553-5, or second portion 553-6 disposed between the folding portion 551, folding portion 551-1, folding portion 551-2, folding portion 551-3, folding portion 551-4, folding portion 551-5, or folding portion 551-6 and the first portion 552, first portion 552-1, first portion 552-2, first portion 552-3, first portion 552-4, first portion 552-5, or first portion 552-6, the second portion 553, second portion 553-1, second portion 553-2, second portion 553-3, second portion 553-4, second portion 553-5, or second portion 553-6 including an adhesive area a and a non-adhesive area b or non-adhesive area b′. In one or more embodiments, the second portion 553, second portion 553-1, second portion 553-2, second portion 553-3, second portion 553-4, second portion 553-5, or second portion 553-6 having a ratio of the adhesive area a per unit area increasing from the folding portion 551, folding portion 551-1, folding portion 551-2, folding portion 551-3, folding portion 551-4, folding portion 551-5, or folding portion 551-6 toward the first portion 552, first portion 552-1, first portion 552-2, first portion 552-3, first portion 552-4, first portion 552-5, or first portion 552-6, and a third portion 554, third portion 554-1, third portion 554-2, third portion 554-3, third portion 554-4, third portion 554-5, or third portion 554-6 disposed between the plurality of folding areas, first filing area F1 and second folding area F2, and having a ratio of the adhesive area a per unit area increasing in a direction away from each of the plurality of folding areas, first filing area F1 and second folding area F2, may be included.

While embodiments have been illustrated and described above, the present disclosure is not limited to the aforementioned specific embodiments. Those skilled in the art should appreciate that various modifications may be made to the embodiments without departing from the subject matter of the present disclosure as defined by the appended claims, and also that such modifications are not to be understood individually from the technical spirit or prospect of the present disclosure.

What is claimed is:

1. A display module comprising:
a display panel;
a support plate supporting the display panel, the support plate comprising a bendable region comprising a lattice pattern, a first region spaced apart from the bendable region in a first direction, and a second region between the first region and the bendable region; and
an adhesive layer between the display panel and the support plate, the adhesive layer comprising an adhesive area and a non-adhesive area,
wherein the adhesive layer further comprises:
a first portion on the first region of the support plate, the first portion comprising the adhesive area; and
a second portion on the second region of the support plate, the second portion comprising the adhesive area and the non-adhesive area, a ratio of the adhesive area per unit area of the second portion increasing along the first direction.

2. The display module of claim 1, wherein, in the second:
the adhesive area comprises a plurality of geometric structures, and a size of each of the plurality of geometric structures is increased in the first direction, and
the non-adhesive area at least partially surrounds each of the plurality of geometric structures.

3. The display module of claim 2, wherein each of the plurality of geometric structures has a polygonal shape.

4. The display module of claim 2, wherein each of the plurality of geometric structures has a circular shape or an oval shape.

5. The display module of claim 1, wherein the adhesive area comprises an adhesive material, and
wherein the non-adhesive area comprises an open space.

6. The display module of claim 1, wherein the second portion comprises an edge area provided at an end portion in a second direction perpendicular to the first direction, and the edge area has a shape in which a width of the non-adhesive area gradually decreases along the first direction.

7. The display module of claim 6, wherein the edge area comprises a boundary line where the adhesive area and the non-adhesive area face each other, and the boundary line is curved along the first direction.

8. The display module of claim 1, wherein the ratio of the adhesive area per unit area of the second portion gradually increases from an end portion along a second direction that is perpendicular to the first direction and toward a center of the second portion.

9. The display module of claim 1, wherein, in the second portion:
the adhesive area has a pattern shape in which a plurality of geometric structures are spaced apart from each other,
the non-adhesive area is between the plurality of geometric structures, and
an interval between the plurality of geometric structures decreases along the first direction.

10. The display module of claim 1, wherein,
in the second portion:
the adhesive area has a pattern shape in which a plurality of geometric structures are spaced apart from each other,
the non-adhesive area is between the plurality of geometric structures, and
an interval between the plurality of geometric structures decreases from an end portion along a second direction, perpendicular to the first direction, toward a center of the second portion.

11. The display module of claim 1, wherein the adhesive area comprises an adhesive material, and
wherein the non-adhesive area comprises the adhesive material and a non-adhesive material that covers at least one surface of the adhesive material.

12. The display module of claim 1, wherein the non-adhesive area of the second portion comprises:
a first non-adhesive portion comprising an open space; and
a second non-adhesive portion comprising a non-adhesive material.

13. The display module of claim 1, wherein, in the second portion:
the non-adhesive area has a pattern shape in which a plurality of geometric structures are arranged, and
the adhesive area surrounds each of the plurality of geometric structures.

14. The display module of claim 13, wherein the second portion has a pattern shape in which an area of each of the plurality of geometric structures of the non-adhesive area decreases along the first direction.

15. A bendable electronic device comprising:
the display module according to claim 1; and
a housing structure supporting the display module and configured to fold.

16. A display module comprising:
a display panel;
a support plate supporting the display panel, the support plate comprising a bendable region comprising a lattice pattern, a first region spaced apart from the bendable region in a first direction, and a second region between the first region and the bendable region; and
an adhesive layer between the display panel and the support plate, the adhesive layer comprising an adhesive area and a non-adhesive area,
wherein the adhesive layer further comprises:
a folding portion on the bendable region of the support plate and comprising the non-adhesive area, the non-adhesive area occupying an entirety of the folding portion;
a first portion on the first region of the support plate, the first portion comprising the adhesive area; and
a second portion on the second region of the support plate, the second portion comprising the non-adhesive area at end portions along a second direction perpendicular to the first direction, and the adhesive area between the end portions in the second direction.

17. The display module of claim 16, wherein the second portion comprises an edge area, provided at the end portions along the second direction, and the edge area has a shape in which a width of the non-adhesive area is gradually decreased along the first direction.

18. The display module of claim 17, wherein the edge area comprises a boundary line where the adhesive area and the non-adhesive area face each other, and the boundary line is curved along the first direction.

19. A bendable electronic device comprising:
the display module according to claim 16; and
a housing structure supporting the display module and configured to fold.

20. An electronic device comprising:
a housing structure; and
a display module comprising a plurality of bendable folding areas, coupled to the housing structure, and configured to visually expose at least a partial area thereof,
wherein the display module comprises:
a display panel;
a support plate supporting the display panel, the support plate comprising a bendable region comprising a lattice pattern and overlapping the plurality of bendable folding areas, a first region spaced apart from the bendable region in a first direction, and a second region between the first region and the bendable region; and
an adhesive layer between the display panel and the support plate, the adhesive layer comprising an adhesive area and a non-adhesive area,
wherein the adhesive layer further comprises:
a folding portion on the bendable region of the support plate and comprising the non-adhesive area, the non-adhesive area occupying an entirety of the folding portion;
a first portion on the first region of the support plate, the first portion comprising the adhesive area;
a second portion on the second region of the support plate, the second portion comprising the adhesive area and the non-adhesive area and having a ratio of the adhesive area per unit area of the second portion increasing from the bendable region toward the first portion; and
a third portion between the plurality of bendable folding areas, the third portion comprising the adhesive area and the non-adhesive area and having a ratio of the adhesive area per unit area of the third portion increasing along a direction away from each of the plurality of bendable folding areas.
